(19) United States
(12) Patent Application Publication
(10) Pub. No.: US 2024/0102744 A1
(43) Pub. Date: Mar. 28, 2024

(54) THERMAL ENERGY MANAGEMENT KITS

(71) Applicant: Phase Change Energy Solutions, Inc., Greensboro, NC (US)

(72) Inventors: Reyad I. Sawafta, Greensboro, NC (US); Jason Baker, Greensboro, NC (US); Taylor Lawing, Greensboro, NC (US); Byron Owens, Greensboro, NC (US); A. Scott Queen, Greensboro, NC (US); Rami M. Saeed, Greensboro, NC (US); Michael Beatty, Greensboro, NC (US)

(73) Assignee: Phase Change Energy Solutions, Inc., Greensboro, NC (US)

(21) Appl. No.: 17/768,903

(22) PCT Filed: Oct. 15, 2020
(86) PCT No.: PCT/US2020/055753

§ 371 Date: Apr. 14, 2022

Related U.S. Application Data
(60) Provisional application No. 62/915,511, filed on Oct. 15, 2019.

(51) Int. Cl. F28D 20/02

(52) U.S. Cl. CPC F28D 20/023; F28D 2021/0035

(57) ABSTRACT

Thermal energy management kits are described herein. A thermal energy management kit described herein includes one or more thermal storage cells. Individual thermal storage cells have a container. The container may be formed from a thermally conductive material and has an interior volume. The thermal storage cell further includes a phase change material disposed within the interior volume of the container. Thermal energy management kits described herein may optionally further include one or more mounting structures.

### CROSS REFERENCE TO RELATED APPLICATIONS

This application claims priority pursuant to 35 U.S.C. § 119 to U.S. Provisional Patent Application Ser. No. 62/915,511, filed on Oct. 15, 2019, which is hereby incorporated by reference in its entirety.

### FIELD

The present disclosure relates to thermal energy management kits including a phase change material (PCM) or latent heat storage material, and to methods of absorbing and releasing thermal energy using such systems.

### BACKGROUND

Certain types of equipment, such as mechanical or electrical equipment or telecommunications equipment or other electronic equipment, generate significant amounts of thermal energy when in use, and/or operate more efficiently within a specific temperature range. Some previous efforts to manage the temperature of such equipment (or of environments containing such equipment, such as data centers) have used traditional heating, ventilation, and air conditioning (HVAC) systems. However, the use of HVAC systems alone to manage the temperature of certain environments can be costly and/or energy-inefficient. Moreover, for some environments, such as small rooms or closets, HVAC systems alone may be insufficient for establishing or maintaining a desired temperature. Therefore, improved systems and methods are needed for managing the temperature of certain environments, including environments in which telecommunications equipment or other heat-generating or temperature-sensitive equipment is housed.

### SUMMARY

Thermal energy management kits or systems and associated components and methods are described herein. Such kits, systems, components, and methods, in some cases, can provide one or more advantages compared to some existing systems and methods. In some embodiments, for example, a kit or method described herein can provide more versatile thermal energy management, including in a manner that is modular and/or suitable for interior environments having a small footprint, area, or volume, such as information technology (IT) closets or data rooms (e.g., having a size of 25-200 ft²). Additionally, a kit or system described herein, in some instances, is easier to install, use, and maintain, as compared to some other systems. For example, in some cases, a kit described herein can be wall mounted in 5-15 minutes within a wall space of 2 ft×2 ft. Moreover, kits or systems described herein can be used for a variety of end-uses or applications, including but not limited to thermal energy management for industrial, commercial, and/or residential buildings that include or use a heating, ventilating, and air conditioning (HVAC) system. Kits or systems described herein may particularly be used for managing excess heat or thermal energy from electronic or telecommunications equipment or other equipment, or for maintaining a desired temperature or operating temperature range for such equipment. Alternatively, in other implementations, a kit or system described herein can be used to provide resilience or to maintain a desired temperature for a different environment, such as refrigerator, freezer, or cold room. Thermal energy management kits and methods described herein may be used advantageously for other purposes also, as described further herein.

In one aspect, thermal energy management kits are described herein. A thermal energy management kit described herein comprises one or more thermal storage cells. Individual thermal storage cells comprise a container. The container may be formed from a thermally conductive material and has an interior volume. The thermal storage cell further comprises a phase change material disposed within the interior volume of the container. Thermal energy management kits described herein may optionally further comprise one or more mounting structures. The one or more mounting structures are configured to attach the one or more thermal storage cells to a wall, ceiling, or furniture of a room. In certain embodiments, a container of kits described herein has a length, a width, and a depth, wherein a ratio of the length to the width is at least 5:1. In some such embodiments, a ratio of the length to the width is at least 10:1. Further, in some implementations, the container has a first end and a second end, and the thermal storage cell further comprises a first end cap disposed at the first end of the container and a second end cap disposed at the second end of the container, the first end cap and the second end cap being configured to seal the first end and the second end to prevent the flow of the phase change material from within the container.

In another aspect, thermal energy management kits are described herein. In certain implementations, the thermal energy management kit comprises a thermal battery comprising a plurality of thermal storage cells. The thermal energy management kit may further comprise an enclosure, the plurality of thermal storage cells being disposed within the enclosure. In addition, the kit can comprise at least one fan configured to pull air through the enclosure across or through the thermal battery and to exhaust the air external to the enclosure. Such thermal energy management kits are, in some implementations, portable.

In a further aspect, methods of managing the temperature of a room are described herein. Such methods comprise disposing one or more kits described herein into the room. Methods of managing the temperature of a room may further comprise changing the phase of the phase change material from a first phase to a second phase by exposing the phase change material to an ambient temperature in the room below a phase change temperature of the phase change material and reverting the phase change material to the first phase by heating the room with an HVAC system of the room. In certain other embodiments, methods described herein comprise changing the phase of the phase change material from a first phase to a second phase by exposing the phase change material to an ambient temperature of the room above a phase change temperature of the phase change material and reverting the phase change material to the first phase by cooling the room with an HVAC system in the room. In additional embodiments, reverting the phase change material to the first phase and/or the second phase may be performed with an alternative source of heating or cooling, such as a refrigerator, freezer, cooler, or battery or battery array.

These and other implementations are described in more detail in the detailed description which follows.

### BRIEF DESCRIPTION OF THE DRAWINGS

FIG. 1 illustrates a perspective view of a mounting structure according to one embodiment described herein.

FIG. 2 illustrates a perspective view of a thermal storage cell according to one embodiment described herein.

FIG. 3 illustrates a perspective view of an assembled and mounted kit according to one embodiment described herein, including a mounting structure and a thermal storage cell.

FIG. 4 illustrates a perspective view of the thermal storage cell of FIG. 2 assembled with the mounting structure of FIG. 1.

FIG. 5 illustrates a perspective view of an assembled kit according to one embodiment described herein, including a plurality of mounting structures and a plurality of thermal storage cells.

FIG. 6 illustrates a perspective view of a mounting structure according to one embodiment described herein.

FIG. 7 illustrates a perspective view of an assembled kit according to one embodiment described herein, including a plurality of mounting structures and a plurality of thermal storage cells.

FIG. 8 illustrates a side view of a mounting structure and thermal storage cell, assembled, according to one embodiment described herein.

FIG. 9 illustrates a side view of a mounting structure and thermal storage cell, assembled, according to one embodiment described herein.

FIG. 10 illustrates a perspective view of an assembled kit according to one embodiment described herein, including a mounting structure and a thermal storage cell.

FIG. 11 illustrates a perspective view of an assembled kit according to one embodiment described herein, including a mounting structure and a thermal storage cell.

FIG. 12 illustrates a top or side view of a thermal storage cell with two protrusions as mounting connectors, according to one embodiment described herein. Mounting structures (brackets) are also illustrated around the protrusions.

FIG. 13 illustrates a perspective view of the assembly of FIG. 12.

FIG. 14 illustrates a close-up side view of the mating or coupling of a bracket and mounting connector from the embodiment of FIG. 12.

FIG. 15 illustrates a top or side view of a thermal storage cell with two protrusions as mounting connectors, according to one embodiment described herein. Mounting structures (brackets) are also illustrated around the protrusions.

FIG. 16 illustrates a perspective view of the assembly of FIG. 15.

FIG. 17 illustrates a close-up side view of the mating or coupling of a bracket and mounting connector from the embodiment of FIG. 15.

FIG. 18 illustrates a front view of a mounting structure according to one embodiment described herein, along with two side views of different cross-sectional variations of the mounting structure (left and right, bottom), according to some embodiments described herein.

FIG. 19 illustrates a front view of a mounting structure (bracket) coupled or attached to a plurality of thermal storage cells snapped into the bracket. One thermal storage cell is also shown in side view, individually and while being snapped into the bracket, according to one embodiment described herein.

FIG. 20 illustrates a side view of a thermal storage cell having two different protrusions for two different mounting orientation options, according to some embodiments described herein. The thermal storage cell is shown individually and also with a mounting structure (bracket) in two variations.

FIG. 21 illustrates a front view of a mounting structure (bracket) coupled or attached to a plurality of thermal storage cells snapped into the bracket, according to one embodiment described herein. A spacer is also shown (front and back views), including how it can be assembled with the thermal storage cells.

FIG. 22 illustrates a front view of an assembled kit comprising a movable or mobile frame and a stack of thermal storage cells, according to one embodiment described herein.

FIG. 23 illustrates a perspective view of a thermal storage cell according to one embodiment described herein.

FIG. 24 illustrates a perspective view of a battery according to one embodiment described herein.

FIG. 25 illustrates a perspective view of a kit according to one embodiment described herein.

FIG. 26 illustrates a perspective view of a thermal storage cell according to one embodiment described herein.

FIG. 27 illustrates a perspective view of a component of a kit according to one embodiment described herein.

FIG. 28 illustrates a perspective view of a thermal storage cell according to one embodiment described herein.

FIG. 29 illustrates a perspective view of a battery according to one embodiment described herein.

FIG. 30 illustrates a perspective partial cutaway view of the battery of FIG. 29.

FIG. 31 illustrates a perspective view of a battery according to one embodiment described herein.

FIG. 32 illustrates a perspective partial cutaway view of the battery of FIG. 31.

### DETAILED DESCRIPTION

Implementations and embodiments described herein can be understood more readily by reference to the following detailed description, examples, and drawings. Elements, apparatus, and methods described herein, however, are not limited to the specific implementations presented in the detailed description, examples, and drawings. It should be recognized that these implementations are merely illustrative of the principles of the present disclosure. Numerous modifications and adaptations will be readily apparent to those of skill in the art without departing from the spirit and scope of the disclosure.

In addition, all ranges disclosed herein are to be understood to encompass any and all subranges subsumed therein. For example, a stated range of “1.0 to 10.0” should be considered to include any and all subranges beginning with a minimum of 1.0 or more and ending with a maximum value of 10.0 or less, e.g., 1.0 to 5.3, or 4.7 to 10.0, or 3.6 to 7.9. Similarly, as will be clearly understood, a stated range of “1 to 10” should be considered to include any and all subranges beginning with a minimum of 1 or more and ending with a maximum value of 10 or less, e.g., 1 to 6, or 7 to 10, or 3.6 to 7.9.

All ranges disclosed herein are also to be considered to include the end points of the range, unless expressly stated otherwise. For example, a range of “between 5 and 10,” “from 5 to 10,” or “5-10” should generally be considered to include the end points of 5 and 10.

### I. THERMAL ENERGY MANAGEMENT KITS

In one aspect, thermal energy management kits are described herein. Thermal management kits consistent with the present disclosure comprise or include a “thermal storage battery”. Not intending to be bound by theory, a thermal storage battery may be operable to absorb heat from an environment and to optionally return the heat to the environment, specifically to moderate or alter the temperature of the environment thus “recharging” the thermal battery. Upon reaching a temperature at or above a desired set point, the thermal storage battery's thermal energy absorption may assist in holding the set point temperature while the room is being heated. Upon the environment reaching a temperature below the desired set point, the thermal storage battery may optionally release the thermal energy back into the environment. This release of thermal energy may assist in holding the set point temperature during cooling. In operation, the thermal energy absorption step may time shift temperature increase in the environment to above the desired set point, which may, in some instances, allow HVAC or other active environmental cooling arrangements to use or draw power during off-peak time frames, which may reduce stress or strain on an energy grid. Additionally, this time shifting may also permit the user to purchase power during off-peak times when the power may come at a lower cost, thus providing savings to the user. Further, time shifting of a temperature change above a desired set point may profile a buffer during power outages or failure of regular environmental cooling measures, such as HVAC. Such systems therefore can provide an additional layer of protection from having the environment reach a temperature out of desired tolerances to protect the contents of the environment, which may include sensitive or expensive equipment. The environment may also be adapted to house people, thus maximizing the comfort or livability of the environment. Moreover, time shifting of the temperature moving above a desired set point may also permit normal exterior day/night temperature shifts to assist in moderate the temperature of the environment. In such use cases, overall energy usage is not merely time shifted, but may be reduced, thus providing energy and potentially cost savings to the user. In this manner, a thermal storage battery may provide on-demand cooling.

It is also possible for a thermal storage battery described herein to provide on-demand heating. Thermal storage batteries described herein may be operable to provide heat to an environment, and to optionally reabsorb heat from the environment at a later time, thus “recharging” the thermal battery. Upon the environment reaching a temperature above the desired set point, the thermal storage battery may optionally reabsorb the thermal energy back from the environment. This absorption of thermal energy may assist in holding the set point temperature during heating. As discussed above, this release and optional reabsorption of thermal energy from the environment may time shift temperature changes above or below the desired set point within the environment for off-peak hours, or to permit normal day/night temperature cycling to manage the temperature of the environment within tolerance more effectively. It may also permit normal temperature control measures, such as an HVAC system, to operate more efficiently or to operate during off-peak hours. In addition, such systems may form part or all of a temperature buffer system in the event of a partial or catastrophic failure of normal or routine thermal management systems.

In some embodiments, a kit or described herein can provide more versatile thermal energy management consistent with the above discussion, including in a manner that is modular and/or suitable for interior environments having a small footprint, area, or volume, such as information (IT) closets or data rooms (e.g., having a size of 25-200 ft²). However, as would be understood by one having ordinary skill in the art, thermal energy management kits may be disposed in, and optionally attached to (or furniture disposed in) any room not inconsistent with the objectives of the present disclosure. For example, in some embodiments, kits described herein may be disposed in a trailer (e.g., such as may be used for the transport of goods), a shelter, or a warehouse environment or a room disposed therein. Moreover, kits or systems described herein can be used for a variety of end-uses or applications, including but not limited to thermal energy management for industrial, commercial, and/or residential buildings that include or use a heating, ventilating, and air conditioning (HVAC) system. In certain other instances, a heat source of a room in which a thermal energy management kit described herein may be disposed is a battery or a plurality of batteries. Any batteries may be used in such an environment such as, without limitation, electrochemical batteries. For example, in an environment adapted to store an array or collection of batteries, such as a data center, telecommunications shelter or storage trailer, solar farm, or power grid backup shelter, thermal management kits described herein can be used to manage temperature at or near a desired set point to assist with routine temperature management, such as an HVAC solution. Additionally and/or alternatively, kits described herein can be used as an emergency temperature buffer in the event that routine thermal management solutions fail or go offline in order to permit time for repairs or for power to be restored. Such as solution may be useful where excess or backup batteries are used for emergency usage, such as to bridge gaps in power supply by a traditional power grid. Additionally, such applications specifically contemplated herein include battery collections or arrays for the storage of surplus or backup energy in a solar panel farm or solar panel array.

In addition, the room can be a data room, a data storage or processing center, or an IT closet. Thus, in some embodiments, a kit described herein can be used to manage heat or thermal energy in a computing, telecommunications, electronics, or data context. However, it is to be understood that kits and associated methods described herein are not necessarily limited to such uses or such rooms or other environments. For instance, in some cases, a kit described herein can be disposed or installed in a different room or environment, such as a refrigerator, freezer, or cold room. In such cases, the kit (and associated methods) can be used to establish or maintain a desired temperature or temperature range for cold or frozen applications, such as may be preferred for the storage of food or pharmaceuticals in a cool, cold, or frozen environment.

a. Thermal Storage Cells and Components Thereof.

Thermal energy management kits and thermal storage batteries of the kits described herein comprise one or more thermal storage cells. Thermal storage cells may be configured in an array or grouping or may be mounted or otherwise disposed within an environment separately. A thermal storage battery may comprise a single thermal storage cell, although thermal energy management kits may have any number of thermal storage cells. The number of thermal storage cells may be selected for the desired heat capacity of the thermal storage battery formed by the thermal energy management kit. In some embodiments, a thermal energy management kit may be modular, with thermal storage cells being added or removed based on the desired heating or cooling capacity of the thermal storage battery. Thermal storage cells described herein comprise a container and a phase change material disposed within an interior volume of the container.

Containers of thermal storage cells described herein comprise an exterior surface defining an interior or internal volume. A container used in a thermal storage cell of a thermal energy management kit described herein can have any shape or arrangement consistent with the present disclosure. For example, in some embodiments, the container has the form or shape of a plate, blade, grid, or panel. The plate, blade, grate, grid, or panel (referred to collectively as a “container” below, for convenience) can be generally square or rectangular in cross section (e.g., such that the container is a relatively short or “flat” rectangular cylinder). Additionally, the container may include a fill spout. The fill spout (when in in an open configuration, as opposed to a closed or sealed configuration) provides fluid communication between the interior volume and the external environment of the container. The exterior surface of the container includes a front side, a back side, and at least four corners. The fill spout is disposed at one of the corners of the exterior surface.

Further, in some preferred embodiments, a container described herein also comprises a cap. More particularly, such a cap can cover, enclose, or “complete” the corner where the fill spout is disposed. Thus, in some cases, for instance, surfaces of the cap align with the exterior surface of the container to conceal the corner fill spout.

For example, in some embodiments, the container can be generally square or rectangular in cross section (e.g., such that the container is a relatively short or “flat” rectangular cylinder). Moreover, in certain preferred embodiments, the container has a relatively high surface area to volume ratio. For example, in some cases, the container can have a surface area to volume ratio (e.g., in units of cm²/cm³) of at least 1:2, at least 1:3, at least 1:4, at least 1:5, at least 1:10, at least 1:20, at least 1:50, or at least 1:100. In some embodiments, the container has a surface area to volume ratio between about 1:3 and 1:100, between about 1:3 and 1:50, between about 1:5 and 1:100, between about 1:5 and 1:50, or between about 1:10 and about 1:100. Similarly, in some cases, the average thickness of the container can be relatively small compared to the average length and average width of the container. For instance, in some embodiments, the average length and the average width of the container are at least 5 times, at least 10 times, at least 20 times, or at least 50 times the average thickness of the container. In some cases, the average length and the average width of the container are 5-100, 5-50, 5-20, 10-100, or 10-50 times the average thickness of the container.

Moreover, in some preferred implementations, the exterior surface of the container further comprises one or more protrusions. The protrusions extend in an orthogonal or substantially orthogonal (e.g., within 15 degrees, within 10 degrees, or within 5 degrees of orthogonal) direction from the back side of the container. As further described herein, in some cases, the one or more protrusions are configured or operable to form a gap between the back side of the container and an adjacent surface, such as a wall against which the container is disposed or another container with which the container is stacked. The protrusions can thus act as a spacer.

In addition, in some especially preferred embodiments, the exterior surface of the container further comprises one or more channels extending from the front side to the back side and connecting the front side to the back side. These channels may also be described as through holes or perforations of the container.

In some cases, at least 90% of the interior volume of a container is occupied by the PCM (which may be referred to below as a “thermal management material”). In other cases, at least 95%, at least 96%, at least 97%, at least 98%, or at least 99% of the interior volume is occupied by the thermal management material. In other embodiments, the thermal management material occupies 50-100%, 60-100%, 70-100%, 80-100%, 90-100%, 90-99%, 90-98%, 95-100%, or 95-98% of the interior volume of the container.

The exterior surface of container, in some embodiments, is operable to facilitate heat transfer between an external environment and the interior volume, or between the external environment and a PCM disposed within the interior volume. For example, in some embodiments, the exterior surface can comprise or be formed from one or more materials that facilitate heat transfer, such as a thermal exchange material or a thermally conductive material. Any material operable to permit thermal exchange from the container to the external environment can be used. Thermally conductive materials which may form one or more materials of the container described herein have a thermal conductivity greater than or equal to a thermal conductivity of the PCM disposed within the interior volume of the container(s). Specifically, in some embodiments, the thermally conductive material has a thermal conductivity higher than a thermal conductivity of the PCM within the interior volume of the container. Thermally conductive materials which may form one or more materials of the container described herein may have a thermal conductivity of at least 0.2 W/m*K. For example, in some embodiments, thermally conductive materials have a thermal conductivity of at least 0.4 W/m*K, such as at least 0.5 W/m*K, at least 0.75 W/m*K, or at least W/m*K. In some instances, a thermally conductive material has a thermal conductivity of between 0.2 and 450 W/m*K, such as between 0.4 W/m*K and 450 W/m*K, 0.2 and 400 W/m*K, 0.2 and 350 W/m*K, 0.2 and 300 W/m*K, 0.2 and 250 W/m*K, 0.2 and 200 W/m*K, 0.2 and 150 W/m*K, or 0.2 and 100 W/m*K. In some instances, the thermally conductive material has a thermal conductivity of between 0.2 and 90 W/m*K, 0.2 and 75 W/m*K, 0.2 and 50 W/m*K, and 0.2 and 25 W/m*K. In certain other implementations, the thermally conductive material has a thermal conductivity of between 0.4 and 400 W/m*K, 0.4 and 350 W/m*K, 0.4 and 300 W/m*K, 0.4 and 250 W/m*K, 0.4 and 200 W/m*K, 0.4 and 150 W/m*K, or 0.4 and 100 W/m*K. In yet further embodiments, the thermally conductive material has a thermal conductivity of between 0.4 and 90 W/m*K, 0.4 and 75 W/m*K, 0.4 and 50 W/m*K, and 0.4 and 25 W/m*K. In still further embodiments, the thermally conductive material has a thermal conductivity of at least 7 W/m*K, such as between 7 and 450 W/m*K. Additionally, in some instances, a thermal conductivity of the container is at least one order of magnitude higher than a thermal conductivity of the PCM, such as at least two orders of magnitude higher, or at least three orders of magnitude higher. Not intending to be bound by theory, a container being formed from one or more materials which has a thermal conductivity one or more orders of magnitude higher than the PCM within the container may facilitate heat absorption and/or dissipation, thereby reducing “charging” time of the thermal storage cell and increasing the buffer time of the thermal storage battery while being “discharged.”

Some non-limiting examples of materials usable for containers of thermal storage cells described herein include a polymeric or plastic material (such as a polyethylene, polypropylene, polyethylene terephthalate, polyvinyl chloride, polycarbonate, polyoxymethylene, acrylonitrile butadiene styrene, or polyether ether ketone), a metal or mixture or alloy of metals (such as aluminum), and a composite material (such as a composite fiber or fiberglass). It is to be understood that the material forming or used to form the exterior surface of the container, in some preferred embodiments, can generally form or define the entire body of the container or substantially the entire body of the container. Additionally, the material used to form the exterior surface (or the entire body or substantially the entire body of the container) can be non-breathable or non-permeable to water, and/or non-flammable or fire-resistant. Moreover, in some instances, the material used to form the exterior surface (or the entire body or substantially the entire body of the container) is non-electrically conductive, or has low or minimal electrical conductivity, such that the material is considered an electrical insulator rather than an electrical conductor. The use of a non-electrically conductive material to form the exterior surface of a container described herein may be especially desirable, for example, if the container is placed in a room or space in which sensitive and/or expensive electronic devices are used, such as a telecommunications data room or data center in which computer systems and associated components are housed.

Further, in some cases, a thermally conductive material described above can be dispersed within a non-thermally conductive material or within a less thermally conductive material. In some embodiments, for example, a thermally conductive material comprises a paint, ink, or pigment, or a metal dispersed in a paint, ink, or pigment. Moreover, the paint, ink, or pigment can be used to form a design or decorative feature on the exterior surface of the container.

Additionally, the material forming the exterior surface (or the entire body or substantially the entire body of the container) can have any thickness not inconsistent with the objectives of the present disclosure. In some embodiments, the thickness is selected based on a desired mechanical strength and/or thermal conductivity. For example, in some cases, the average thickness of the material forming the exterior surface (or the entire body or substantially the entire body of the container) is less than 10 mm, less than 5 mm, less than 3 mm, or less than 1 mm. In some embodiments, the average thickness is between 1 and 10 mm, between 1 and 5 mm, between 1 and 3 mm, between 3 mm and 10 mm, between 3 mm and 5 mm, or between 5 mm and 10 mm.

Moreover, in some embodiments, the exterior surface of the container can have one or more features, such as edges that are flat, rounded, bullnose, or beveled connecting the front and back sides of the exterior surface. Other features of a container can include one or more recessed regions, protrusions, and/or channels. In some cases, one or more features present on the front side of the container are also present on the back side of the container. In other instances, the front side can include one or more features absent from the back side of the container, or vice versa.

In some embodiments, the exterior surface can further comprise one or more channels, through-holes, or perforations. As described above, one or more channels present in a container can increase the surface area of the container or air flow “through” the container (from the front side to the back side). The presence, number, and size of channels can also be selected based on a desired thermal storage capacity of the container (e.g., as determined by a volume or mass of PCM disposed within the interior volume of the container, where a larger total channel volume corresponds to a smaller total volume of PCM, for a given size container). The channels can have any shape not inconsistent with the objectives of the present disclosure. For example, in some cases, a channel has a shape (e.g., a sectional shape when viewed from the front or the back side of the container) that is generally circular, oval, or oblong. The shape can also be a polygonal shape having sharp or rounded corners. Further, in some embodiments, the channels (or the “sidewalls” of the channels) can have straight, rounded, beveled, or bullnose edges connecting the front and back sides of the exterior surface.

Additionally, in some example embodiments, a container described herein further comprises a fill spout having an opening in fluid communication with the interior volume of the container and an external environment of the container. In some cases, the fill spout is generally cylindrical in shape. However, other shapes may also be used. The fill spout, in some embodiments, is disposed at one of the corners of the exterior surface. In some embodiments, the fill spout further comprises an air outlet. The air outlet is operable to allow displaced air to exit the internal volume while filling the thermal management container via the fill spout.

Containers described herein can be formed from any material not inconsistent with the objectives of the present disclosure. For example, in some embodiments, containers described herein comprise or are formed from a material which is operable to facilitate heat transfer between an external environment and the interior volume, or between the external environment and a PCM disposed within the interior volume. For example, in some embodiments, the container's exterior surface can comprise or be formed from one or more materials that facilitate heat transfer, such as a thermal exchange material or a thermally conductive material. Any material operable to permit thermal exchange from the container to the external environment can be used. Some non-limiting examples of materials suitable for use in forming a container described herein include a polymeric or plastic material (such as a polyethylene, a polypropylene, polyethylene terephthalate, polyvinyl chloride, polycarbonate, polyoxymethylene, acrylonitrile butadiene styrene, or a polyether ether ketone), a metal or mixture or alloy of metals (such as aluminum), and a composite material (such as a composite fiber or fiberglass). It is to be understood that the material forming or used to form the container or the exterior surface of the container, in some preferred embodiments, can generally form or define the entire body of the container or substantially the entire body of the container.

In some alternative embodiments, the container may be formed as an elongated structure such as a bar, tube, or other elongated prism structure having an internal volume which may be filled or partially filled with a PCM. In such implementations, the container has a first end and a second end spaced apart from the first end, the separate ends defining a length. The container in such embodiments also defines a width. The container may have a large length to width ratio. For example, in some embodiments, the ratio of the length to the width is at least 5:1, such as at least 10:1, at least 15:1, or at least 20:1 Additionally, a ratio of the length to the width may be even larger, such as at least 25:1, at least 30:1, or as large as at least 50:1, or at least 100:1. In some embodiments, the container has a length to width ratio between 5:1 and 100:1, between 5:1 and 50:1, between 5:1 and 25:1, between 5:1 and 20:1, between 5:1 and 15:1, or between 5:1 and 10:1. In some cases, the length to width ratio may fall between 10:1 and 100:1, such as between 10:1 and 50:1, between 10:1 and 25:1, between 10:1 and 20:1, or between 10:1 and 15:1. Other ratios are also possible, such as between 15:1 and 100:1, between 15:1 and 50:1, between 15:1 and 25:1, or between 15:1 and 20:1. Additionally, a ratio of the length to the width may be between 20:1 and 100:1, such as between 20:1 and 50:1, or 25:1 and 50:1. Moreover, a ratio of the length to the width may be between 25:1 and 100:1, such as between 50:1 and 100:1, or between 25:1 and 50:1.

In some such implementations in which the container is formed as an elongated structure such as a bar, tube, or other elongated prism, one or more of the first end and the second end may be open or closed. An “open” end as referenced herein indicates that the end of the container may be able to receive or release PCM from the end, as in the case of the fill spout for plate-like embodiments discussed above. Additionally, such embodiments may facilitate manufacturing of the body portion of the container from a larger or longer container having the same or substantially the same cross-sectional shape. In embodiments in which one or both of the first end and the second end may be open, a thermal storage cell may further comprise a first end cap disposed at the first end of the container and/or a second end cap disposed at the second end of the container.

End caps of thermal storage cells described herein may be configured or adapted to seal one or both of the first end and the second end to prevent the flow of the phase change material from within the container. “Flow” of phase change material is not intended to be limited specifically to phase change material (or, as reference above “PCM”) solely in the liquid state, and may also refer to other states, such as solid or gel, which may be inserted into or slidably removed from an interior volume of the container. Additionally and/or alternatively, the flow of PCM may include PCM which is not entirely in a single state, such as a partially melted or partially solidified PCM. The end caps, therefore, may prevent or substantially limit the flow or other removal of the PCM from within the interior volume of the container in any state or states of the PCM in order to ensure that the PCM is held within the container.

In some implementations, one or more end caps described herein may be removably attached to one or more ends of the container. Any removable attachment configuration not inconsistent with the objectives of the present disclosure may be used such as, without limitation, locking detents, interference fit, snap-fit or snap-together connection, brackets or removable locking or mounting connectors, or a releasable adhesive. In certain other embodiments, one or more end caps described herein may be non-removably attached to the container after an initial assembly step. Any non-removable connection method or configuration not inconsistent with the objectives of the present disclosure may be used. For example, one or more end caps may be attached to the container by bonding by an adhesive, welding or soldering, brazing, riveting, or metal stitching. However, it is to be understood that methods of attachment of one or more end caps which may otherwise be damaging, detrimental, or deleterious to the PCM may be performed prior to insertion of the PCM on one end, with one or more other end caps being installed or attached in a manner which is non-detrimental or minimally detrimental to the PCM. In certain embodiments, the container has a first end which is capped or sealed with an integrally formed cap or end portion, with an end cap being inserted or attached to an opposing end. In this manner, one or more sections or portions of the container may have maximal sealing and/or structural integrity while permitting the insertion or filling of PCM to an interior volume of the container. Additionally, in certain embodiments, the container does not have an end cap. In some such embodiments, the container may be injection filled at one or more points along a periphery or a long a length thereof and subsequently sealed by any manner not inconsistent with the objectives of the present disclosure, such as by a rubber stopper (or stopper formed from any material suitable for such function) or by an adhesive or seal-forming material.

In addition to one or more end caps, the thermal storage cell may comprise any number of sealing members which may be used in combination with the container and the end cap or end caps. These sealing members may aid in preventing the flow of the PCM from within the container. Any sealing member consistent with the present disclosure may be used. For example, in some embodiments, one or more of the sealing members may take the form of a gasket or an O-ring. The sealing member or members may be specifically sized or shaped to correspond to the size or shape of the container. Alternatively and/or additionally, the sealing member(s) may be flexible to conform to a shape of the container to form an air tight seal or a liquid tight seal to prevent or minimize the transfer of PCM from an interior volume of the container to an exterior environment and/or to minimize the flow of air between an exterior environment of the container and the interior volume of the container. Sealing members of kits described herein can be formed from any material not inconsistent with the objectives of the present disclosure. For example, in some embodiments, sealing members may be formed from an elastomeric material which may be readily deformed, and which reverse quickly to nearly original size and form when the load causing the deformation has been removed. The sealing members may comprise or be formed from, without limitation, a natural rubber, isoprene rubber (polyisoprene), butadiene rubber (polybutadiene), styrene-butadiene rubber, a butyl rubber (such as isobutylene-isoprene rubber, chlorobutyl rubber, or bromobutyl rubber), nitrile rubber, nitrile-butadiene rubber, acrylonitrile rubber, epichlorohydrin rubber, ethylene-propylene rubber, ethylene-propylene-diene rubber, chloroprene rubber, polyacrylate rubber, polyurethane rubber, fluorocarbon rubber, silicone rubber, polysuphide rubber, ethylene-vinyl acetate copolymer, polypropylene oxide rubber, chlorinated polyethylene, or a rubber blend.

Containers having the elongated form factor as described herein may, in some instances, have any cross-sectional shape not inconsistent with the objectives of the present disclosure. In certain embodiments, the container(s) may have a circular or substantially circular cross-sectional shape. In certain other instances, the container or containers may have a polygonal cross-sectional shape, such as rectangular, pentagonal, hexagonal, or heptagonal, although any number of sides or faces of the cross-sectional shape may be used. Additionally, in some embodiments, the container or containers may have a cross-sectional shape that is star-like or substantially star like, with a number of vertices of the cross-sectional shape being spaced away from or proximally positioned relative to a center point of the cross-sectional shape and alternating vertices being spaced away from or distally positioned relative to the center point of the cross-sectional shape. These alternating vertices may be characterized as “heat fins” or “heat transfer fins” or “thermal energy fins” or “thermal energy transfer fins.” Not intending to be bound by theory, such cross-sectional shapes may increase a surface area of contact between air in the environment with an external surface of the container and/or increase a surface area of contact between the PCM within the interior of the container and the container. This arrangement may facilitate heat transfer between the PCM and the external environment. Further, such an arrangement may facilitate even distribution of thermal energy into or out of the PCM in order to disperse phase transition more evenly across the PCM during “recharging” or “discharge” cycles of the thermal storage battery.

In some embodiments, a cross-sectional shape of the container has at least one substantially flat and/or substantially linear portion on a first side and a rounded or semi-circular portion on an opposite side. In such configurations, a container or a plurality of containers may form a shelf or shelf-like surface with a flat surface defined by the flat or substantially linear portions of the containers. In some such embodiments, containers may be joined together at a first, proximal end of the containers on a vertical surface of the room or environment and optionally at a second, distal end of the containers. The distal end of the containers may similarly be joined to a vertical surface of the room or environment or may be joined to one another and cantilevered from the proximal end. One or more containers in such an arrangement may be joined or affixed to additional vertical surfaces such as within a refrigerator, freezer, server rack, or cabinet.

Additionally, in certain implementations, an end cap or end caps of containers described herein may be configured to act as a connector which engages or attaches to a mounting structure. For example, in some embodiments, one or more end caps have a slot or recess adapted to engage with a protrusion or hook on a mounting structure. In certain embodiments, the mounting structure may be integrally formed with a wall or furniture of the room or environment in which the container is disposed. For example, in some cases, the furniture is or comprises a refrigerator, freezer, or cooler and includes integrally formed mounting structures otherwise adapted to receive a shelf or shelving structure. In such cases, the end cap or end caps may be configured to engage with the mounting structure(s) to mount the container(s) to the refrigerator, freezer, or cooler. However, as understood by one having ordinary skill in the art, such an arrangement may also be used in other applications, such as integrally formed mounting structures in data racks, shelving units, or other furniture. In other embodiments, the mounting structure is not integrally formed with the wall, floor, ceiling, or furniture of the environment and is instead attached thereto. In certain implementations, the thermal storage cells may be specifically adapted or configured to be inserted or engaged with a “blank” slot or rack of a data cabinet, data shelf, or data rack.

As described herein, a kit comprises a PCM disposed within the interior volume of the plate(s) of the kit. As understood by one of ordinary skill in the art, a PCM can store or release thermal energy in the process of undergoing a phase transition (such as between a solid state and a liquid state, or between a solid state and a gel state). For example, a PCM can absorb thermal energy from the external environment (e.g., produced by equipment or other heat sources in a room, such as a data center) and use the thermal energy to undergo a phase transition (e.g., a melting event), without increasing in temperature. The absorbed thermal energy is instead “stored” as latent heat within the PCM. In this manner, the temperature of the external environment can be decreased (as compared to what the temperature would be in the absence of the PCM). At a later time (e.g., at night or when the heat sources within the environment are producing less excess thermal energy), the PCM can release the stored thermal energy (in the form of latent heat) by undergoing the opposite phase transition as before (e.g., a freezing event). In this manner, the PCM can be “recharged” for another cycle of thermal energy absorption (e.g., during the day or when the heat sources within the environment are producing a relatively large amount of excess heat).

Any PCM or combination of PCMs not inconsistent with the objectives of the present disclosure may be used in a component or method described herein. Moreover, the PCM (or combination of PCMs) used in a particular instance can be selected based on a relevant operational temperature range for the specific end use or application. For example, in some cases, the PCM has a phase transition temperature within a range suitable for cooling or helping to maintain a desired temperature or set point in a residential or commercial building or portion thereof. As understood by one having ordinary skill in the art, a phase transition temperature described herein (such as a phase transition temperature of “X” ° C., where X may be 23° C., for example) may be represented as a normal distribution of temperatures centered on X° C. In addition, as understood by one having ordinary skill in the art, a PCM described herein can exhibit thermal hysteresis, such that the PCM exhibits a phase change temperature difference between the “forward” phase change and the “reverse” phase change (e.g., a solidification temperature that is different from the melting temperature). In some such instances, the building or portion thereof is a data center or data room, or an attic. In other embodiments, the building or portion thereof is a refrigerated room, warehouse, or other space, or is a freezer. In other instances, the PCM has a phase transition temperature suitable for the thermal energy management of so-called waste heat. In some embodiments, the PCM has a phase transition temperature within one of the ranges of Table 1 below.

TABLE 1
Phase transition temperature ranges for PCMs (at a pressure of 1 atm).
Phase Transition Temperature Ranges

| | |
|---|---|
| 450-550° | C. |
| 300-550° | C. |
| 70-100° | C. |
| 60-80° | C. |
| 40-50° | C. |
| 16-23° | C. |
| 16-18° | C. |
| 15-20° | C. |
| 6-8° | C. |
| −40 to −10° | C. |

Moreover, in certain embodiments, it may be desirable or even preferable that a phase transition temperature of the PCM or mixture of PCMs is at or near a desired set-point temperature in an interior of a room or an external environment. Any desired room temperature or external temperature and associated phase transition temperature can be used. For example, in some embodiments, a phase transition temperature is between about 15° C. and about 32° C. at 1 atm, such as between about 17° C. and about 30° C. at 1 atm, between about 19° C. and about 28° C., or between about 21° C. and about 26° C. at 1 atm. Further, in some cases, a phase transition temperature is between about 17° C. and about 32° C. at 1 atm, such as between about 19° C. and about 32° C. at 1 atm, between about 21° C. and about 32° C. at 1 atm, between about 23° C. and about 32° C. at 1 atm, or between about 25° C. and about 32° C. at 1 atm. Moreover, in some embodiments, a phase transition temperature is between about 15° C. and about 30° C. at 1 atm, such as between about 15° C. and about 28° C. at 1 atm, between about 15° C. and about 26° C. at 1 atm, or between about 15° C. and about 24° C. at 1 atm.

As described further herein, a particular range can be selected based on the desired application. For example, PCMs having a phase transition temperature of 20-25° C. can be especially desirable to assist in the cooling of data centers, while PCMs having a phase transition temperature of 6-8° C. can be especially desirable for maintaining the temperature of a refrigerated space. As another non-limiting example, PCMs having a phase transition between −40° C. and −10° C. can be preferred for use in commercial freezer cooling.

Further, a PCM of a device or method described herein can either absorb or release energy using any phase transition not inconsistent with the objectives of the present disclosure. For example, the phase transition of a PCM described herein, in some embodiments, comprises a transition between a solid phase and a liquid phase of the PCM, or between a solid phase and a mesophase of the PCM. A mesophase, in some cases, is a gel phase. Thus, in some instances, a PCM undergoes a solid-to-gel transition. A solid to solid transition is also possible.

Moreover, in some cases, a PCM or mixture of PCMs has a phase transition enthalpy of at least about 50 kJ/kg or at least about 100 kJ/kg. In other embodiments, a PCM or mixture of PCMs has a phase transition enthalpy of at least about 150 kJ/kg, at least about 200 kJ/kg, at least about 300 kJ/kg, or at least about 350 kJ/kg. In some instances, a PCM or mixture of PCMs has a phase transition enthalpy between about 50 kJ/kg and about 350 kJ/kg, between about 100 kJ/kg and about 350 kJ/kg, between about 100 kJ/kg and about 220 kJ/kg, or between about 100 kJ/kg and about 250 kJ/kg.

In addition, a PCM of a device or method described herein can have any composition not inconsistent with the objectives of the present disclosure. In some embodiments, for instance, a PCM comprises an inorganic composition. In other cases, a PCM comprises an organic composition. In some instances, a PCM comprises a salt hydrate. Suitable salt hydrates include, without limitation, CaCl₂·6H₂O, Ca(NO₃)₂·3H₂O, NaSO₄·10H₂O, Na(NO₃)₂·6H₂O, Zn(NO₃)₂·2H₂O, FeCl₃·2H₂O, Co(NO₃)₂·6H₂O, Ni(NO₃)₂·6H₂O, MnCl₂·4H₂O, CH₃COONa·3H₂O, LiC₂H₃O₂·2H₂O, MgCl₂·4H₂O, NaOH H₂O, Cd(NO₃)₂·4H₂O, Cd(NO₃)₂·1H₂O, Fe(NO₃)₂·6H₂O, NaAl(SO₄)₂·12H₂O, FeSO₄·7H₂O, Na₃PO₄·12H₂O, Na₂B₄O₇·10H₂O, Na₃PO₄·12H₂O, LiCH₃COO·2H₂O, and/or mixtures thereof. The PCM may also be water. In other embodiments, the PCM is not water.

In other embodiments, a PCM comprises a fatty acid. A fatty acid, in some embodiments, can have a C4 to C28 aliphatic hydrocarbon tail. Further, in some embodiments, the hydrocarbon tail is saturated. Alternatively, in other embodiments, the hydrocarbon tail is unsaturated. In some embodiments, the hydrocarbon tail can be branched or linear. Non-limiting examples of fatty acids suitable for use in some embodiments described herein include caprylic acid, capric acid, lauric acid, myristic acid, palmitic acid, stearic acid, arachidic acid, behenic acid, lignoceric acid, and cerotic acid. In some embodiments, a PCM described herein comprises a combination, mixture, or plurality of differing fatty acids. For reference purposes herein, it is to be understood that a chemical species described as a “Cn” species (e.g., a “C4” species or a “C28” species) is a species of the identified type that includes exactly “n” carbon atoms. Thus, a C4 to C28 aliphatic hydrocarbon tail refers to a hydrocarbon tail that includes between 4 and 28 carbon atoms.

In some embodiments, a PCM comprises an alkyl ester of a fatty acid. Any alkyl ester not inconsistent with the objectives of the present disclosure may be used. For instance, in some embodiments, an alkyl ester comprises a methyl ester, ethyl ester, isopropyl ester, butyl ester, or hexyl ester of a fatty acid described herein. In other embodiments, an alkyl ester comprises a C2 to C6 ester alkyl backbone or a C6 to C12 ester alkyl backbone. In some embodiments, an alkyl ester comprises a C12 to C28 ester alkyl backbone. Further, in some embodiments, a PCM comprises a combination, mixture, or plurality of differing alkyl esters of fatty acids. Non-limiting examples of alkyl esters of fatty acids suitable for use in some embodiments described herein include methyl laurate, methyl myristate, methyl palmitate, methyl stearate, methyl palmitoleate, methyl oleate, methyl linoleate, methyl docosahexanoate, methyl ecosapentanoate, ethyl laurate, ethyl myristate, ethyl palmitate, ethyl stearate, ethyl palmitoleate, ethyl oleate, ethyl linoleate, ethyl docosahexanoate, ethyl ecosapentanoate, isopropyl laurate, isopropyl myristate, isopropyl palmitate, isopropyl stearate, isopropyl palmitoleate, isopropyl oleate, isopropyl linoleate, isopropyl docosahexanoate, isopropyl ecosapentanoate, butyl laurate, butyl myristate, butyl palmitate, butyl stearate, butyl palmitoleate, butyl oleate, butyl linoleate, butyl docosahexanoate, butyl ecosapentanoate, hexyl laurate, hexyl myristate, hexyl palmitate, hexyl stearate, hexyl palmitoleate, hexyl oleate, hexyl linoleate, hexyl docosahexanoate, and hexyl ecosapentanoate.

In some embodiments, a PCM comprises a fatty alcohol. Any fatty alcohol not inconsistent with the objectives of the present disclosure may be used. For instance, a fatty alcohol, in some embodiments, can have a C4 to C28 aliphatic hydrocarbon tail. Further, in some embodiments, the hydrocarbon tail is saturated. Alternatively, in other embodiments, the hydrocarbon tail is unsaturated. The hydrocarbon tail can also be branched or linear. Non-limiting examples of fatty alcohols suitable for use in some embodiments described herein include capryl alcohol, pelargonic alcohol, capric alcohol, undecyl alcohol, lauryl alcohol, tridecyl alcohol, myristyl alcohol, pentadecyl alcohol, cetyl alcohol, heptadecyl alcohol, stearyl alcohol, nonadecyl alcohol, arachidyl alcohol, heneicosyl alcohol, behenyl alcohol, lignoceryl alcohol, ceryl alcohol, and montanyl alcohol. In some embodiments, a PCM comprises a combination, mixture, or plurality of differing fatty alcohols.

In some embodiments, a PCM comprises a fatty carbonate ester, sulfonate, or phosphonate. Any fatty carbonate ester, sulfonate, or phosphonate not inconsistent with the objectives of the present disclosure may be used. In some embodiments, a PCM comprises a C4 to C28 alkyl carbonate ester, sulfonate, or phosphonate. In some embodiments, a PCM comprises a C4 to C28 alkenyl carbonate ester, sulfonate, or phosphonate. In some embodiments, a PCM comprises a combination, mixture, or plurality of differing fatty carbonate esters, sulfonates, or phosphonates. In addition, a fatty carbonate ester described herein can have two alkyl or alkenyl groups described herein or only one alkyl or alkenyl group described herein.

Moreover, in some embodiments, a PCM comprises a paraffin. Any paraffin not inconsistent with the objectives of the present disclosure may be used. In some embodiments, a PCM comprises n-dodecane, n-tridecane, n-tetradecane, n-pentadecane, n-hexadecane, n-heptadecane, n-octadecane, n-nonadecane, n-eicosane, n-heneicosane, n-docosane, n-tricosane, n-tetracosane, n-pentacosane, n-hexacosane, n-heptacosane, n-octacosane, n-nonacosane, n-triacontane, n-hentriacontane, n-dotriacontane, n-tritriacontane, and/or mixtures thereof.

In addition, in some embodiments, a PCM comprises a polymeric material. Any polymeric material not inconsistent with the objectives of the present disclosure may be used. Non-limiting examples of suitable polymeric materials for use in some embodiments described herein include thermoplastic polymers (e.g., poly(vinyl ethyl ether), poly(vinyl n-butyl ether) and polychloroprene), polyethylene glycols (e.g., CARBOWAX® polyethylene glycol 400, CARBOWAX® polyethylene glycol 600, CARBOWAX® polyethylene glycol 1000, CARBOWAX® polyethylene glycol 1500, CARBOWAX® polyethylene glycol 4600, CARBOWAX® polyethylene glycol 8000, and CARBOWAX® polyethylene glycol 14,000), and polyolefins (e.g., lightly crosslinked polyethylene and/or high density polyethylene).

Additional non-limiting examples of phase change materials suitable for use in some embodiments described herein include BioPCM materials commercially available from Phase Change Energy Solutions (Asheboro, North Carolina), such as BioPCM-(-8), BioPCM-(-6), BioPCM-(-4), BioPCM-(-2), BioPCM-4, BioPCM-6, BioPCM 08, BioPCM-Q12, BioPCM-Q15, BioPCM-Q18, BioPCM-Q20, BioPCM-Q21, BioPCM-Q23, BioPCM-Q25, BioPCM-Q27, BioPCM-Q30, BioPCM-Q32, BioPCM-Q35, BioPCM-Q37, BioPCM-Q42, BioPCM-Q49, BioPCM-55, BioPCM-60, BioPCM-62, BioPCM-65, BioPCM-69, and others.

It is further to be understood that a device described herein can comprise a plurality of differing PCMs, including differing PCMs of differing types. Any mixture or combination of differing PCMs not inconsistent with the objectives of the present disclosure may be used. In some embodiments, for example, a thermal management plate or panel comprises one or more fatty acids and one or more fatty alcohols. Further, as described above, a plurality of differing PCMs, in some cases, is selected based on a desired phase transition temperature and/or latent heat of the mixture of PCMs.

Further, in some embodiments, one or more properties of a PCM described herein can be modified by the inclusion of one or more additives. Such an additive described herein can be mixed with a PCM and/or disposed in a device described herein. In some embodiments, an additive comprises a thermal conductivity modulator. A thermal conductivity modulator, in some embodiments, increases the thermal conductivity of the PCM. In some embodiments, a thermal conductivity modulator comprises carbon, including graphitic carbon. In some embodiments, a thermal conductivity modulator comprises carbon black and/or carbon nanoparticles. Carbon nanoparticles, in some embodiments, comprise carbon nanotubes and/or fullerenes. In some embodiments, a thermal conductivity modulator comprises a graphitic matrix structure. In other embodiments, a thermal conductivity modulator comprises an ionic liquid. In some embodiments, a thermal conductivity modulator comprises a metal, including a pure metal or a combination, mixture, or alloy of metals. Any metal not inconsistent with the objectives of the present disclosure may be used. In some embodiments, a metal comprises a transition metal, such as silver or copper. In some embodiments, a metal comprises an element from Group 13 or Group 14 of the periodic table. In some embodiments, a metal comprises aluminum. In some embodiments, a thermal conductivity modulator comprises a metallic filler dispersed within a matrix formed by the PCM. In some embodiments, a thermal conductivity modulator comprises a metal matrix structure or cage-like structure, a metal tube, a metal plate, and/or metal shavings. Further, in some embodiments, a thermal conductivity modulator comprises a metal oxide. Any metal oxide not inconsistent with the objectives of the present disclosure may be used. In some embodiments, a metal oxide comprises a transition metal oxide. In some embodiments, a metal oxide comprises alumina.

In other embodiments, an additive comprises a nucleating agent. A nucleating agent, in some embodiments, can help avoid subcooling, particularly for PCMs comprising finely distributed phases, such as fatty alcohols, paraffinic alcohols, amines, and paraffins. Any nucleating agent not inconsistent with the objectives of the present disclosure may be used. In still other instances, an additive comprises a fire retardant or fire-resistant material.

A container described herein can be made in any manner not inconsistent with the objectives of the present disclosure. In some cases, for instance, a plastic or metal container is made by a molding or casting, such as by injection molding. Other methods of making a container described herein may also be used, as readily understood by those of ordinary skill in the art. Similarly, the manner of filling a container described herein with a PCM is not particularly limited. In some cases, a gravimetric method is used. In other cases, pressurized PCM is injected into the fill spout of a container described herein.

b. Mounting Structures

Thermal energy management kits described herein may optionally further comprise one or more mounting structures. Mounting structures described herein are configured or adapted to attach the one or more thermal storage cells to a wall, ceiling, or furniture of a room. Any mounting structure consistent with the objectives of the present disclosure may be used. Mounting structures described herein are, in some instances, configured to be removably attached to the wall, ceiling, or furniture of the room. Any configuration permitting removable assembly not inconsistent with the objectives of the present disclosure can be used.

Mounting structures and mounting connections thereof which are described herein are separate from the thermal storage cell and are not integrally formed with the container or the thermal storage cell. For example, in some embodiments, the mounting structure can be multi-part or may be configured to engage with a mated or matched portion of the container to attach the one or more thermal storage cells to the wall, ceiling, or furniture of the room. In some such implementations, the container may comprise a mounting connector for coupling or mating to the mounting structures of the kit. The manner in which the container and mounting connector may engage or interact with one another is not specifically limited. In some embodiments, the container comprises a male mounting connector, the one or more mounting structures comprise a female mounting connector, and the male mounting connector of the container mates to the female mounting connector of the mounting structures. For reference herein, a “male” connector is shaped or constructed in such a way that it can be inserted into a receptacle (or a “female”) connector to ensure a reliable physical connection. A male connector may bear one or more protrusions which may be associated with one or more indentations, grooves, slots or other receiving structures on a female connector. In some implementations, the male mounting connector is a protrusion integrally formed with the container. The male mounting connector may alternatively be formed as a separate component which is attached to the container. The attachment may be removable, such as being mechanically attached by a snap-in connection, using one or more fasteners such as a zip-tie, or by a bolt or screw. The manner of removable attachment is not specifically limited by these examples. Alternatively, the male connector may be non-removably attached to the container, such as by bonding (as by an adhesive, epoxy, or the like) or by welding. In certain embodiments, the female mounting connector may comprise a bracket, such as a U-shaped or C-shaped bracket, in certain non-limiting examples.

In some embodiments, the container comprises a female mounting connector, the one or more mounting structures comprise a male mounting connector, and the female mounting connector of the container mates to the male mounting connector of the mounting structures. In some such embodiments, the female mounting connector may be integrally formed with the container. The female mounting connector may alternatively be formed as a separate component which is attached to the container. The attachment may be removable, such as being mechanically attached by a snap-in connection, using one or more fasteners such as a zip-tie, or by a bolt or screw. The manner of removable attachment is not specifically limited by these examples. Alternatively, the male connector may be non-removably attached to the container, such as by bonding (as by an adhesive, epoxy, or the like) or by welding. Female mounting connectors may form a U-shaped or C-shaped connector, in certain non-limiting examples.

In certain implementations, one or more mounting connectors may have a female mounting portion and a male mounting portion which work in combination with one another. In such embodiments, the container may have both a male mounting connector and a female mounting connector which are sized and positioned so as to engage with a corresponding female mounting connector and male mounting connector, respectively. Additionally, kits described herein may comprise or include multiple male mounting connectors associated with a single container and/or multiple female mounting connectors associated with a single container. Mounting structures may have a corresponding number of matched mounting connectors. For example, a container may have 2 male mounting connectors and the mounting structure(s) may have 2 corresponding female mounting connectors. In certain other embodiments, a container may have a plurality of male mounting connectors and/or a plurality of female mounting connectors, but which are associated or engaged with only a single mounting structure connector at a time. In such configurations, the container may be positioned in a variety of orientations or vertical or horizontal positions as required by space limitations of the environment in which they are disposed. Conversely, a mounting structure may have a plurality of mounting connectors to receive or engage a single mounting connector of a container in a variety of orientations or positions to permit the container to be repositioned depending on the space constraints of the environment.

Moreover, in some implementations, a single mounting structure may have multiple mounting connections which are adapted to receive multiple containers. Such a configuration may be useful where a user desires to have thermal storage battery with a plurality of thermal storage cells, forming an array of cells which may be adjacent to one another. Such embodiments may comprise a rail or rail system, such as parallel rails into which one or more containers can “snap,” slide, or otherwise fit. The container(s) can be attached or coupled to, received by, or fitted into one or more mounting structures in other ways as well. In some embodiments a kit described herein comprises a plurality of containers configured to attach to the one or more mounting structures in a parallel or substantially parallel configuration. For reference purposes herein, an orientation that is “substantially” parallel can be within 15 degrees, within 10 degrees, within 5 degrees, or within 2 degrees of parallel.

In some implementations where a plurality of thermal storage cells are used, the thermal storage cells may have a desired average distance from one another. In some embodiments, the containers are separated from one another by an average distance of 0.3 to 3 inches, such as between 0.3 to 2.5 inches, 0.3 to 2 inches, 0.3 to 1.5 inches, or 0.3 to 1 inches. In certain implementations, the containers are separated from one another by an average distance of 0.5 to 3 inches, 1 to 3 inches, 1.5 to 3 inches, 2 to 3 inches, or 2.5 to 3 inches. Further, in some embodiments, the containers are separated from one another by an average distance of 1 to 3 inches, such as 1 to 2.5 inches, 1 to 2 inches, or 1 to 1.5 inches. In some implementations, thermal energy management kits may comprise or include one or more spacers. The spacers are configured to maintain an average distance between portions of thermal storage cells. For example, a thermal storage cell (or more specifically, a container of the thermal storage cell) may define a proximal end and a distal end, with a proximal end of an individual one of the thermal storage cells being attached or affixed to a mounting structure. In such embodiments, the one or more spacers may be configured to maintain an average distance between the distal ends of adjacent thermal storage cells attached to or disposed within the one or more mounting structures.

Thermal storage cells and, more specifically, containers of thermal storage cells described herein, may be positioned or attached to walls, ceilings, or furniture of the room in a desired orientation relative to a floor of the room. For example, in some embodiments, the one or more thermal storage cells are attached to the wall, ceiling, or furniture in a horizontal or substantially horizontal configuration. In certain other embodiments, the one or more thermal storage cells are attached to the wall, ceiling, or furniture in a vertical or substantially vertical configuration. A “horizontal” or “vertical” configuration, for reference purposes herein, indicates an orientation of a long axis. For example, a “horizontal configuration” indicates that the long axis of the individual thermal storage cells are parallel or substantially parallel to a floor of the room. Likewise, a “vertical configuration” indicates that the long axis of the individual thermal storage cells are perpendicular or substantially perpendicular to a floor of the room. For reference purposes herein, an orientation that is “substantially” horizontal (or vertical or parallel, etc.) can be within 15 degrees, within 10 degrees, within 5 degrees, or within 2 degrees of horizontal (or vertical or parallel, etc.).

In some instances, the one or more mounting structures are removably attached to the wall, ceiling, or furniture of the room. Any removable attachment configuration not inconsistent with the objective of the present disclosure can be used. For example, in some implementations, the mounting structure(s) is/are attached to the wall, ceiling, or furniture of the room with one or more bolts or screws. In additional embodiments, the mounting structure(s) is/are attached to the wall by magnets. In yet further embodiments, the one or more mounting structures are attached to the wall, ceiling, or furniture with a releasable adhesive.

In certain other embodiments, the one or more mounting structures are non-removably attached to the wall, ceiling, or furniture of the room. Any non-removable attachment configuration not inconsistent with the objective of the present disclosure can be used. For example, in some embodiments, the one or more mounting structures are bonded or welded to the wall, ceiling, or furniture of the room.

In yet further implementations, mounting structures described herein can be configured to attach at least two thermal storage cells to the wall, ceiling, or furniture. For example, in some embodiments, a single mounting structure can receive a plurality of thermal storage cells in a parallel or substantially parallel configuration. In one such implementation, a series of parallel female connectors are formed in a single mounting connector. Each female connector may have an open end and a closed end to permit slidable insertion of a male mounting connector of the thermal storage cells from one end, with the opposing end being a retaining portion to prevent the thermal storage cells from sliding beyond the end to retain the thermal storage cells. Such an arrangement may be said to include an end cap integral with or permanently affixed to the one or more mounting structures. In certain embodiments, the open end of the rack assembly may be capped to prevent the thermal storage cells from sliding out of the female connectors of the mounting structures accidentally or unintentionally.

In some embodiments, the one or more mounting structures are adapted or configured to receive the one or more thermal storage cells in a snap-in configuration. In some such implementations, this may be achieved by sizing an opening of the mounting structure to receive a portion of the thermal storage cell in a first orientation (e.g., horizontal), and then “snapping” to lock the thermal storage cell into position after the thermal storage cell is inserted into the opening and rotated 90 degrees.

Mounting structures described herein can have one or more openings or female connector portions which are sized to retain a portion or multiple portions of the thermal storage cells in any desired tolerance range to secure the thermal storage cell in position. For example, in some embodiments, it may be desired to have the thermal storage cell be more easily slid into and out of position for easy replacement. In certain other embodiments, it may be desired that a snug, more secure fit is implemented to prevent the thermal storage cells from being inadvertently moved. Therefore, an opening may be sized to provide an interference fit when the portion of the thermal storage cell is inserted into the opening, a clearance fit when the portion of the thermal storage cell is inserted into the opening, or a transition fit when the portion of the thermal storage cell is inserted into the opening.

In certain implementations, a mounting structure and/or a mounting connector of a mounting structure described herein may comprise or include a hook or another shaped protrusion which is adapted to easily receive a recess or gap in a thermal storage cell for easy replacement of the thermal storage cell. In some such embodiments, an intermediary connector may be used which may cap or close a hook to prevent inadvertent removal of the thermal storage cell without hindering removability entirely. For example, a carabiner configuration may be used such that a hook is implemented in tandem with a locking pin. Other intermediary connectors may also be used consistent with this function.

As described herein above, certain mounting structures may be adapted to receive multiple thermal storage cells. Conversely, mounting structures described herein may be configured or adapted such that multiple mounting connectors of the mounting structures may be associated with a single thermal storage cell. In some such embodiments, a first mounting connector may be attached to a first side of the thermal storage cell, with another mounting connector being associated with an adjacent side of the thermal storage cell. In this manner, the thermal storage cell may be secured along two separate axes, reducing “wobble,” or range of motion while connected, thereby securing the thermal storage cell more thoroughly. Any number of mounting connectors may be associated with a single thermal storage cell. In certain other implementations, multiple mounting connectors may be associated with the same side.

Additionally, mounting connectors may be sized and/or shaped to correspond to the thermal storage cell. For example, in some embodiments, one mounting connector may have a width that is the same as a width of the thermal storage cell. In certain other embodiments, one mounting connector may have a width that is different from (either smaller or larger) a width of the thermal storage cell. In addition, these widths may be mixed and matched in any manner without limitation according to the objectives of the present disclosure.

c. Additional Components or Elements of Thermal Energy Management Kits

Thermal energy management kits described herein may further comprise or include additional components or elements which may facilitate mounting the kits to the one or more thermal storage cells to a wall, ceiling, or furniture of a room. Alternatively, such additional elements may facilitate a thermal energy management function of the kits. Moreover, such additional components or elements may provide additional function or utility to the kits.

For example, in some embodiments, kits described herein further comprise at least one fan that directs air flow from a first side of the thermal storage cells to a second side of the thermal storage cells, where the second side of thermal storage cells is in facing opposition to the first side. Such a fan can facilitate efficient thermal energy transfer by the PCM disposed within the containers of the thermal storage cells. Moreover, in some cases, a kit described herein comprises a plurality of fans. For example, in some instances, a kit comprises a first fan that rotates in a clockwise direction and a second fan that rotates in a counterclockwise direction. In still other embodiments, a kit described herein further comprises a photovoltaic cell or a thermoelectric generator that powers the at least one fan or the first fan and/or the second fan. Any photovoltaic cell or thermoelectric generator not inconsistent with the objectives of the present disclosure may be used. For instance, in some cases, the photovoltaic cell is a thin film photovoltaic cell. Moreover, in some embodiments, the photovoltaic cell gathers or harvests energy from ambient light of the room and/or the thermoelectric generator gathers or harvests energy from a temperature gradient within the room.

A kit described herein, in some instances, further comprises a light source. In some such embodiments, the light source is a night light or a safety light. Moreover, the light can be powered by a photovoltaic cell or a thermoelectric generator, which may be the same as that which powers the fans, if present.

d. Further Configurations of Thermal Energy Management Kits

In certain implementations, thermal energy management kits described herein are not necessarily mounted to a wall, ceiling, or furniture of a room. Embodiments of such thermal energy management kits may have an enclosure which may form a canister, box, or case for the thermal storage battery and/or its thermal storage cells. In this manner, the thermal storage battery may be generally self-contained. Additionally, such embodiments may be portable. A “portable” thermal energy management kit, as referenced herein, may be easily carried or moved between locations, including moving or carrying the thermal energy management kit with common transport or warehouse equipment, such as with a forklift. Alternatively, a portable kit may be disposed on a cart with wheels, and/or wheels may be formed on a container or an enclosure of the thermal energy management kit. In certain other embodiments, a portable kit may have one or more handles to facilitate lifting or carrying by one or more persons.

In some instances, a thermal energy management kit described herein comprises or includes a thermal battery, the thermal battery including a plurality of thermal storage cells, such as at least 2, at least 5, at least 10, at least 15, or at least 20 thermal storage cells. For example, a thermal battery can comprise or include 2-500 thermal storage cells, 2-100 thermal storage cells, 10-500 thermal storage cells, 50-100 thermal storage cells, 2-50 thermal storage cells, 100-150 thermal storage cells, 150-200 thermal storage cells, 200-500 thermal storage cells, or 2-10 thermal storage cells. As would be understood by one having skill in the art, the thermal storage battery of such embodiments may be modular or changeable in nature in order to permit a user to add or remove thermal storage cells depending on the desired thermal mass, thermal energy, or total latent heat. The number “n” of thermal storage cells used provide a total thermal mass or latent heat of n times the average latent heat or thermal mass of the individual cells. In some cases, individual cells may have identical or substantially identical average latent heat or thermal mass, but individual cells may differ as well. In certain embodiments, an individual thermal storage cell may contribute no more than 5% of the total thermal mass or latent heat of the battery. Further, one having ordinary skill in the art would recognize that thermal storage cells of a thermal storage battery described in this section can be any thermal storage cell described in the present disclosure. In addition, any number of thermal storage cells may be used not inconsistent with the objectives of the present disclosure in order to manage the desired thermal energy capacity of the thermal storage battery. In some cases, the thermal storage cells are arranged in stacks. The stacks may be fastened together, and/or may be held together by a band or a bracket. In certain other embodiments, the enclosure holds or retains the stacks of thermal storage cells. The thermal energy management kit of such embodiments may further include an enclosure, with the plurality of thermal storage cells being disposed within the enclosure. Any suitable enclosure may be used consistent with the objectives of the present enclosure. For example, in some implementations, the enclosure is formed as a canister, box, or case to contain the thermal storage batteries. The enclosure may be formed from any material not inconsistent with the objectives of the present disclosure, such as a metal or metal alloy or a plastic. In some embodiments, the enclosure may be formed in a two-part construction, with a first material as an inner enclosure and a second material as an outer container. The first and second material may be the same or they may be different.

The enclosure has at least one air inlet opening to permit air flow through or across the thermal storage battery. In such embodiments, individual thermal storage cells of the kits may have one or more air passageways, so that air which flows through the enclosure passes through or across the thermal storage cells to transfer thermal energy between the air and the thermal storage cells. In some implementations, the at least one air inlet opening is on a bottom of the box, although embodiments are contemplated in which the at least one air inlet opening is on a side of the box. The enclosure further includes an air outlet opening. In some embodiments, the air outlet opening is opposite the air inlet opening to permit air to flow across the full thermal storage battery before being exhausted from the enclosure. In embodiments in which the air inlet opening is on a bottom of the enclosure, the air outlet opening may be on a top of the enclosure. In implementations where the air inlet opening is on a side of the enclosure, the air outlet opening may be on an opposing side of the enclosure.

In some such implementations of kits described herein, one or more additional features or components may be included to further facilitate air flow and, by association, thermal energy transfer. For example, in some embodiments, the kit comprises at least one fan. At least one fan may be configured as an exhaust fan. In such instances, at least one fan may be disposed on top of the enclosure (corresponding to the air outlet opening of the embodiment). Additional fans are also contemplated, such as an optional air inlet fan at the air inlet opening. In addition, the kit may comprise one or more power sources for the fan. In addition, a power source of the system and/or the fan could be associated with a more traditional power grid, such as a power outlet external to and separate from the thermal storage battery. Fans and power sources are described in further detail herein below in the context of kits described herein. In certain instances, the kit may further comprise or include a spacer. In embodiments having an air inlet opening on a bottom of the enclosure, the spacer can provide an air gap between a floor of the room and the bottom of the enclosure. Such an arrangement can permit air flow in configurations where direct contact of the enclosure with the floor may otherwise block air flow. Any spacer not inconsistent with this objective may be used. In some embodiments, the spacer is a platform or a plurality of platforms which together form the air gap. In certain other embodiments, the spacer may be a pallet. A “pallet” as referenced herein is a portable platform on which goods can be moved, stacked, and stored, and which optionally may aid with transport of these goods (such as the thermal energy management kit) with the aid of a forklift. The pallet, therefore, may comprise or include a plurality of slots which may provide the dual purpose of providing air flow while facilitating the blades of a forklift truck to lift and lower the kit for portability.

### II. Methods of Managing Temperature

a. General Methods of Managing Temperature

In another aspect, methods of managing temperature are described herein. Any one or more of the devices or kits or systems, as described above in Section I, can be used in any one or more methods of managing temperature, as described herein.

In some embodiments, methods of managing the temperature of a room or space (such as any room or space described above in Section I) are described herein. Such a room or space can include any room or space not inconsistent with the objectives of the present disclosure. A room or space, for example, has at least three walls, a floor, and a ceiling, and optionally comprises electronic devices, such as electronic servers and/or electronic storage hardware, and/or batteries (such as electrochemical batteries) disposed within the room. In other implementations, a room or space has refrigerated, frozen, or cooled materials. A method of managing the temperature of a room or space, in some embodiments, comprises disposing one or more kits, as described above, in the interior of the room.

In some embodiments, a method further comprises providing at least one fan that directs air flow from the room to the PCM and/or from a PCM to the external environment. In some preferred embodiments, the fan is positioned within a channel, through hole, or perforation. The fan, in concert with one or more recessed regions, one or more channels, and/or one or more gaps, can facilitate heat transfer between a PCM disposed within the interior volume of the plate and an external environment (e.g., the room in which the plate/kit is placed).

In further embodiments, a method of managing the temperature of a room comprises maintaining a temperature of the room between about −50° C. and 50° C. In some cases, a method comprises maintaining a temperature of the room between about −10° C. and 0° C., between about 0° C. and 10° C., between about 17° C. and 25° C., between about 15° C. and 40° C., between about 20° C. and 25° C., between about 20° C. and 30° C., between about 25° C. and 35° C., or between about 30° C. and 40° C.

In some implementations, methods described herein further comprise the following steps: changing the phase of the phase change material from a first phase to a second phase by exposing the phase change material to an ambient temperature in the room below a phase change temperature of the phase change material. Such methods may optionally further comprise reverting the phase change material to the first phase by heating an environment containing the phase change material (as may be disposed in the thermal storage cell). The heat source may be an HVAC system or a refrigeration system of the room. The heat source may also be provided by electronic equipment such as data servers, batteries, or other heat sources. The heating source may be activated or deactivated by a thermostat disposed within an interior of the room. Additionally, in some embodiments, the phase change material may be relocated to another room or environment to heat the phase change material to revert the phase change material to the first phase.

In some embodiments, methods described herein comprise the following steps: changing the phase of the phase change material from a first phase to a second phase by exposing the phase change material to an ambient temperature of the room above a phase change temperature of the phase change material. Such methods may further comprise revering the phase change material to the first change by cooling the room. Any equipment or method of cooling the room consistent with the present disclosure may be used, such as cooling the room with an HVAC or refrigeration system of the room. The HVAC or refrigeration may be activated or deactivated by a thermostat disposed within an interior of the room. Additionally, in some embodiments, the phase change material may be relocated to another room or environment to cool the phase change material to revert the phase change material to the first phase.

b. Additional Methods of Managing Temperature

In another aspect, certain methods of managing temperature may be associated with one or more specific embodiments of a thermal management kit described herein such as those described in the section labeled “d. Further Configurations of Thermal Energy Management Kits.” In some instances, methods of managing temperature described herein comprise disposing the thermal battery in a room or environment. The room or environment may be any room or environment described in the present disclosure such as, without limitation, a refrigerated room or freezer or a refrigerated truck (or “reefer” truck). Additionally, the room or environment may be a temperature controlled and/or refrigerated loading dock, where temperature controls may be difficult to moderate due to frequent or prolonged opening and closing of loading bay doors.

Such methods may further comprise changing the phase of the phase change material from a first phase to a second phase by exposing the phase change material to an ambient temperature in the room above a phase change temperature of the phase change material. Alternatively, the method may comprise changing the phase of the phase change material from a first phase to a second phase by exposing the phase change material to an ambient temperature in the room below a phase change temperature of the phase change material. Consistent with the above discussion in section a, some implementations may include or comprise reverting the phase change material to the first phase by heating or cooling the room with an HVAC or refrigeration system of the room. However, in some implementations of the presently described method, the thermal battery may be relocated to a freezer or refrigerated room to be “recharged,” “primed,” or otherwise reverted to the first phase and then moved or relocated to an environment for “discharge” of the thermal battery to change the phase change material from the first phase to the second phase to maintain a cool or refrigerated environment (such as a refrigerated loading dock or a refrigerated or freezer truck), thereby providing temperature control and/or stability. Additionally, embodiments of thermal batteries described herein comprising or including a pallet or multiple pallets configured as a spacer may be particularly suitable for transport between an environment, such as a refrigerated loading dock, and a charging or priming location, such as a freezer or refrigerator.

In some such implementations, the phase change material has a phase transition temperature between −40 and 18° C., such as between −40 and −10° C., 6 and 8° C., or 16 and 18° C., with certain ranges subsumed within the range of between −40 and 8° C. being used in certain preferred implementations for refrigerated or freezer environments.

### III. DISCUSSION OF THE DRAWINGS

Certain non-limiting implementations or embodiments of thermal management kits or components thereof described herein are illustrated in the attached drawings. The following discussion describes certain features of the drawings in the context of the above discussion, but is not intended to limit the features of the drawings to the description thereof. While certain implementations or embodiments are shown in the attached drawings, other embodiments or implementations are within the scope of the present disclosure, including modifications of the embodiments or implementations shown in the attached drawings.

To facilitate understanding of the following description, the following reference numerals may be used. Reference numerals not provided in the drawings or the following description, but which appear in the index below may be reserved for additional reference purposes.
1000=thermal energy management kit
2000=thermal storage cell
   2001=first thermal storage cell
      2601=first side of a first thermal storage cell
      2701=second side of a first thermal storage cell
   2002=second thermal storage cell
   2100=proximal end of a thermal storage cell
   2200=distal end of a thermal storage cell
   2300=spacers
      2310=average distance provided by spacers
      2320=spacer attachment tabs
   2400=long axis of thermal storage cell
   2500=short axis of thermal storage cell
   2600=first side of a thermal storage cell
   2700=second side of a thermal storage cell
   2800=sealing member
   2900=portion of a thermal storage cell
3000=container of a thermal storage cell
   3100=interior volume of a container
   3300=mounting connector
      3310=male mounting connector
         3311=protrusion
   3400=first end of a container
      3410=first end cap
   3500=second end of a container
      3510=second end cap
4000=mounting structure
   4001=first mounting structure
   4002=second mounting structure
   4100=frame
   4210=bolt or screw
   4220=releasable adhesive
   4230=adhesive
      4231=epoxy
   4300=first end of mounting structure
      4310=opening of first end of mounting structure
   4400=second end of mounting structure
      4410=opening of second end of mounting structure
      4420=end cap portion of second end of mounting structure
   4500=removable end cap of a mounting structure
   4710=female mounting connector of a mounting structure
      4711=bracket
      4712=opening of a female mounting connector
   4720=hook of a mounting structure
5100=wall, ceiling, or furniture of a room or environment
5200=floor of room or environment
6100=fan of a kit
   6110=first fan
   6120=second fan
6200=photovoltaic cell of a kit
6300=thermoelectric generator of a kit
6400=light source of a kit
8000=thermal battery
   8100=thermal storage cell of thermal battery
      8110=stack of thermal storage cells
      8120=air passageway of a thermal storage cell
   8200=enclosure of thermal battery
      8210=top of enclosure
      8220=bottom of enclosure
         8221=air inlet opening
   8300=fan of thermal battery
      8310=air
   8400=spacer of thermal battery
      8410=air gap
D1=direction perpendicular to a parallel or substantially parallel configuration of a plurality of thermal storage cells
X1=length of a container of a thermal storage cell
Y1=width of a container of a thermal storage cell
Y2=width of a first side of a first thermal storage cell
Y3=width of a first mounting structure
Y4=width of a second side of a first thermal storage cell
Y5=width of a second mounting structure
Z1=depth of a container of a thermal storage cell

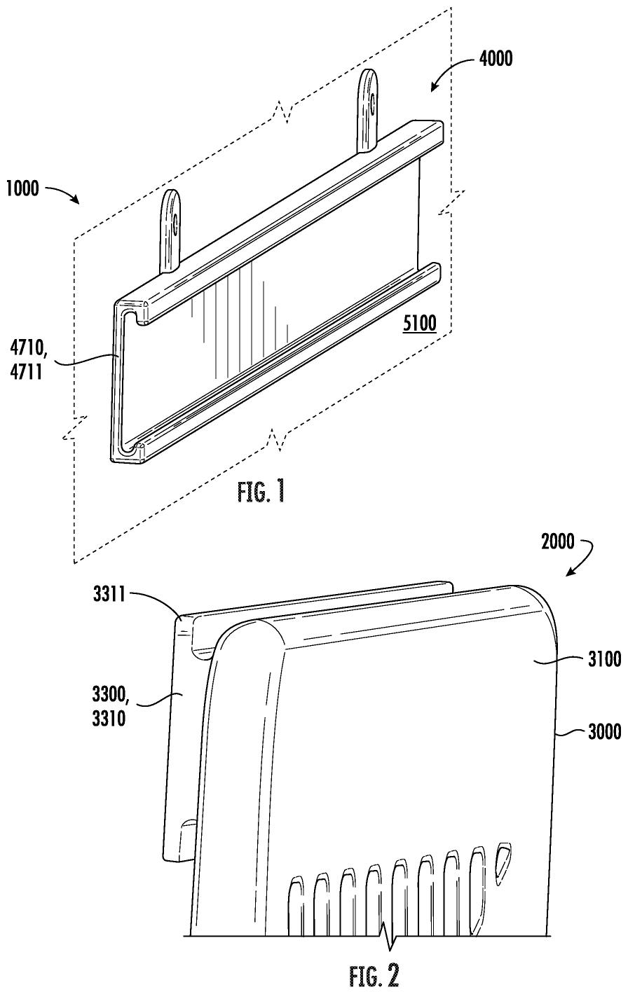

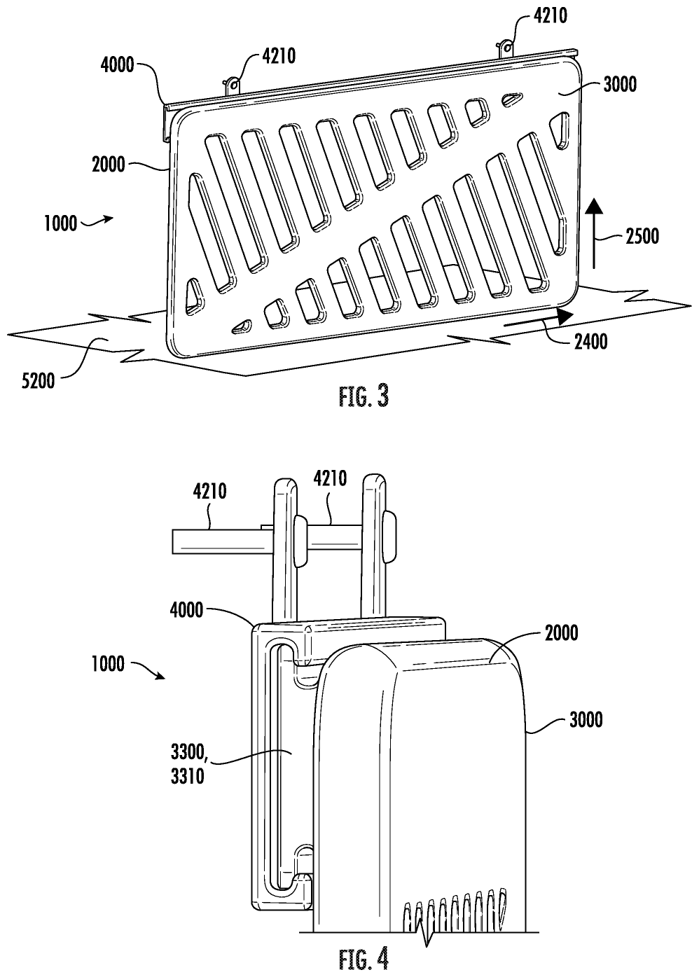

FIGS. 1-4 together illustrate one implementation of a thermal energy management kit 1000 described herein which includes a thermal storage cell 2000. The thermal storage cell 2000 comprises a container 3000 having an interior volume 3100 and phase change material (not shown) disposed within the interior volume 3100 of the container 3000. The kit 1000 further comprises a mounting structure 4000. The mounting structure 4000 is configured to attach the thermal storage cell 2000 to a wall, ceiling, or furniture 5100 of a room. The mounting structure 4000 of FIG. 1 has a female mounting connector 4710 which includes a bracket 4711 and an opening 4712 configured to attach the thermal storage cell 2000 to the wall, ceiling, or furniture 5100. The thermal storage cell 2000 has a container 3000 having a mounting connector 3300 integrally formed therewith. The mounting connector 3300 is a male mounting connector 3310 having a protrusion 3311 to be inserted into or otherwise engage with the opening 4712 of the female mounting connector 4710. FIGS. 3 and 4 show the thermal storage cell 2000 fully engaged with the mounting structure 4000, with the male mounting connector 3310 of the thermal storage cell 2000 engaged with the female mounting connector 4710 of the mounting structure 4000. In the implementation shown in FIGS. 3 and 4, the mounting structure 4000 is attached to the wall, ceiling, or furniture (not shown in FIG. 3 or 4) by bolts or screws 4210. In the embodiment depicted in FIG. 3, a long axis of the thermal storage cell 2400 is parallel or substantially parallel to the floor 5200 of the room and, as such, the thermal storage cell is in a horizontal or substantially horizontal configuration. While FIG. 3 shows the floor 5200 as being adjacent to the thermal storage cell 2000, it is to be understood that this is for reference purposes, and one having skill in the art would understand that the thermal storage cell may be spaced apart from and not in contact with the floor 5200.

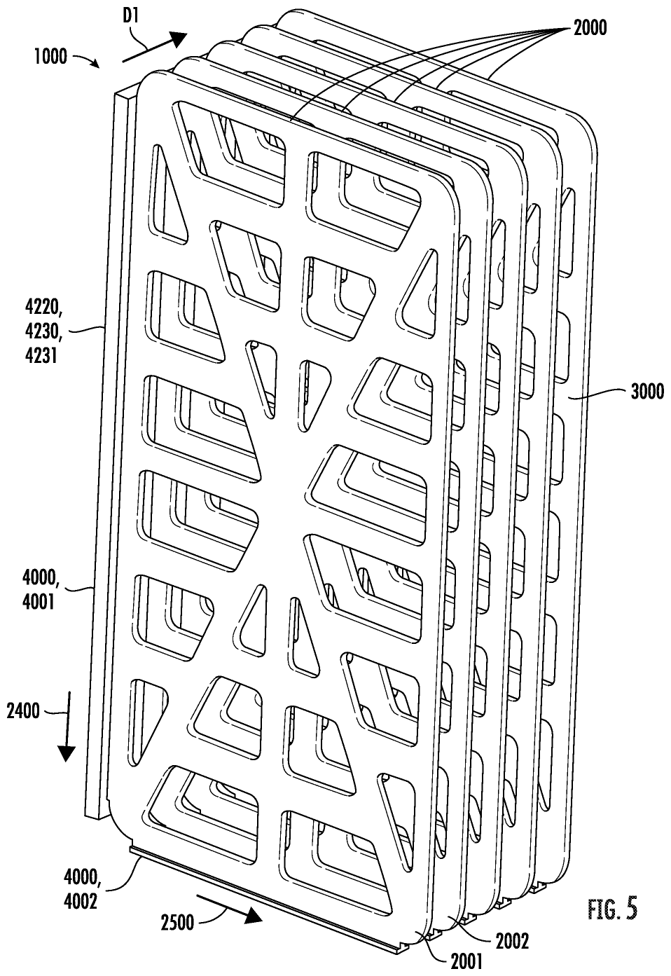

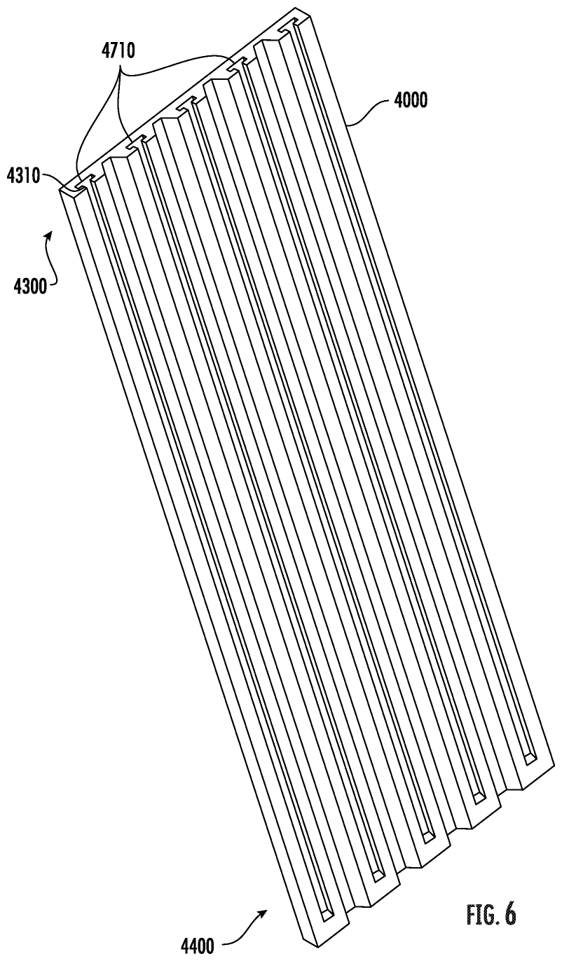

FIG. 5 illustrates one embodiment of a thermal energy management kit 1000 described herein which includes a plurality of thermal storage cells 2000. Individual thermal storage cells 2000 comprise a container 3000 having an interior volume (not shown) and a phase change material (not shown) disposed within the interior volume 3100 of the container 3000. The kit 1000 further comprises one or more mounting structures 4000 which are configured to attach the one or more thermal storage cells 2000 to a wall, ceiling, or furniture (not shown) of a room. The mounting structure 4000 of FIG. 5 includes a first mounting structure 4001 and a second mounting structure 4002 configured to engage an adjacent side of the thermal storage cells 2000. The first mounting structure 4001 includes a rail system which will be discussed in further detail in the context of FIG. 6. The first mounting structure 4001 is attached to the wall, ceiling, or furniture of the room by a releasable adhesive 4220, 4230 such as an epoxy 4231. Each of the first thermal storage cell 2001 and the second thermal storage cell 2002 are positioned vertically or substantially vertically. The long axis 2400 being perpendicular or substantially perpendicular to the floor (not shown) of the room, and the short axis 2500 being parallel or substantially parallel to the floor. The thermal storage cells 2000 are spaced apart from one another at a desired average distance as measured in a direction D1 perpendicular to a parallel or substantially parallel configuration of a plurality of thermal storage cells 2000.

FIG. 6 illustrates one embodiment of a mounting structure 4000 of a thermal energy management kit described herein. The mounting structure shown in FIG. 6 has a first end 4300 and a second end 4400. The first end 4300 has a plurality of openings 4310 which may be considered part of a female mounting connector 4710 of the mounting structure, with each opening 4310 being adapted or configured to receive a corresponding male connector portion of a thermal storage cell (not shown). In the embodiment shown in FIG. 6, the second end 4400 of the mounting structure 4000 is closed or sealed, which provides a stop or an integral cap to prevent further motion of the thermal storage cell once engaged with the second end 4400. The mounting structure 4000 of FIG. 6 permits a plurality of thermal storage cells to be attached to the wall, ceiling, or furniture of the room parallel or substantially parallel to one another, as shown in FIG. 5.

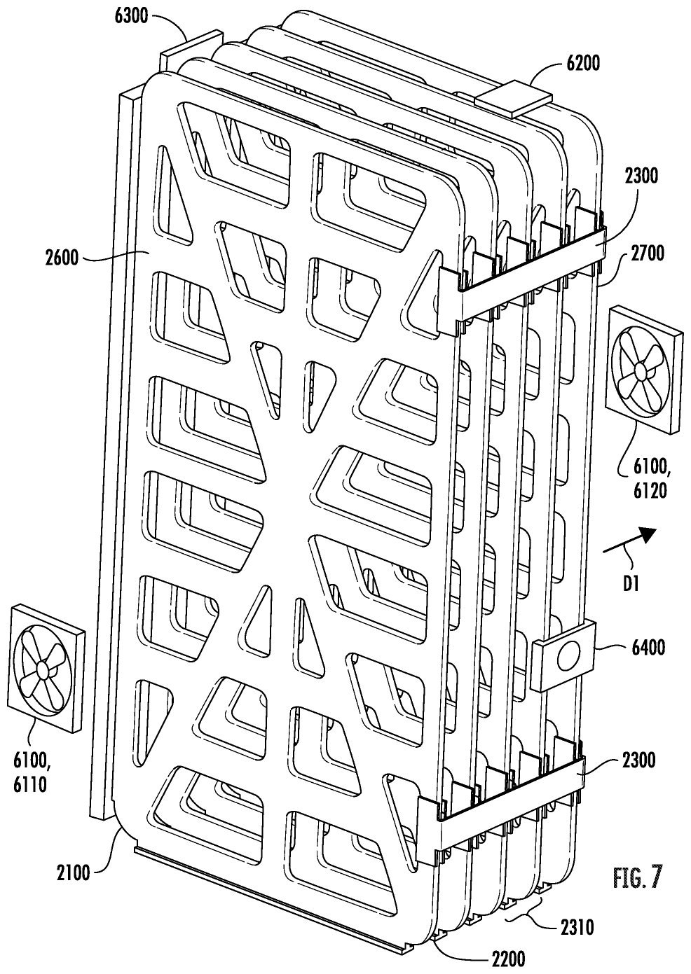

FIG. 7 illustrates an additional embodiment of a thermal energy management kit 1000 described herein. The embodiment of FIG. 7 includes the components and features of FIG. 5 with some additions. For example, FIG. 7 illustrates a fan or multiple fans 6100 including a first fan 6110 and a second fan 6120. The fans can be configured to create or facilitate air flow across the thermal storage cells 2000. Air passageways 8120 (as shown in an alternative embodiment in FIG. 30) in the thermal storage cells 2000 may further facilitate air flow and thermal energy transfer in combination with the one or more fans 6100. For example, the fans 6100 may direct air flow from a first side 2600 of the thermal storage cells 2000 to a second side 2700 of the thermal storage cells 2000. As shown, the first and second sides 2600, 2700 are in facing opposition to one another. The embodiment of FIG. 7 further illustrates a plurality of spacers 2300 which may create or assist in maintaining a desired average distance 2310 provided by spacers. The spacers 2300 may be useful for 3 or more thermal storage cells 2000, however other configurations are also contemplated which may be useful for as few as two thermal storage cells. In the embodiment of FIG. 7, the spacers are located at a distal end 2200 of the thermal storage cells 2000. FIG. 7 also includes a light source 6400 which may be useful in applications where a room may either have no light source of its own, or in use cases where power is out or shut off. To power the one or more fans 6100 and/or light source 6400 in such an event, or even during normal operation to conserve power otherwise provided to the room, the kit 1000 of FIG. 7 further includes both a photovoltaic cell 6200 and a thermoelectric generator 6300. One having ordinary skill in the art would reasonably understand that different configurations, combinations, additions, or subtractions to this configuration are also possible.

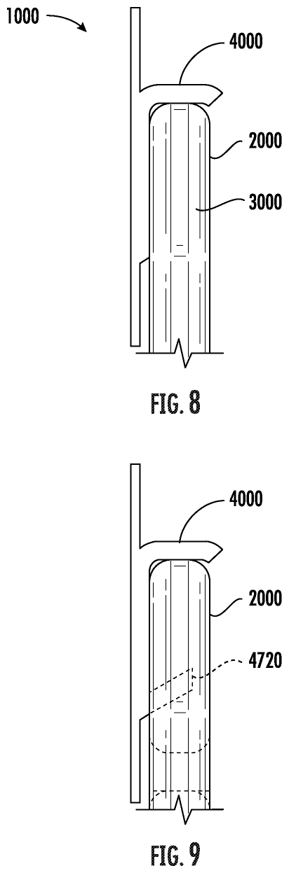

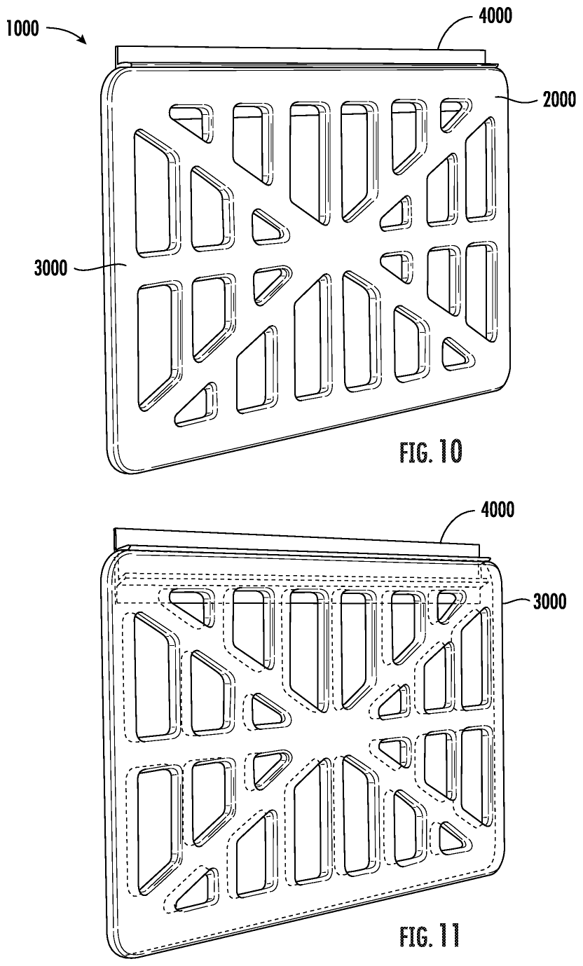

FIGS. 8-11 illustrate an additional embodiment of a thermal energy management kit 1000 as described herein. FIGS. 8 and 9 provide sectional and/or partially transparent views of the embodiment of a thermal energy management kit 1000 shown more fully in FIGS. 10 and 11. FIG. 8 provides a perspective view of the mounting structure 4000 and a portion of the container 3000 of the thermal storage cell 2000 engaged with the mounting structure 4000. FIG. 9 provides a partially transparent view of the embodiment of FIG. 8 to include additional detail of the mounting structure 4000. In an embodiment consistent with these drawings, a container 3000 of a thermal storage cell 2000 may “snap-fit” with the mounting structure 4000. The hook 4720 of the mounting structure 4000 can receive the container 3000 in a first orientation with a plane of the container 3000 being parallel or substantially parallel with a floor of the room, and the container 3000 being rotated 90 degrees into a locked or snapped position within the mounting structure 4000 for a more secure fit. FIGS. 10 and 11 show that the final position of the container 3000 is horizontal or substantially horizontal consistent with the present disclosure, although one having skill in the art may readily recognize that a vertical arrangement is also possible with such a design.

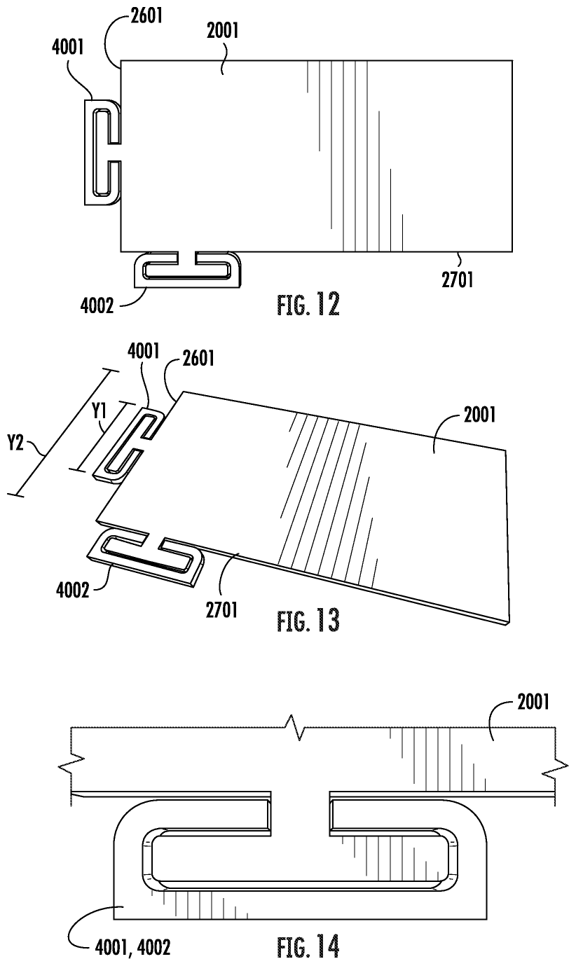

FIGS. 12-14 provide a schematic representation of one or more components of kits 1000 described herein. A first thermal storage cell 2001 having a first side 2601 and a second side 2701 includes male mounting connectors integrally formed therewith (as labeled 3310 in an alternative embodiment discussed herein above). The kit includes a first mounting structure 4001 and a second mounting structure 4002 engaged with the first side 2601 and the second side 2701 respectively. In the embodiment shown in FIG. 13, Y1 indicates a width of the first mounting structure, Y2 indicates a width of the first side 2601. As shown in FIG. 13, the first side 2601 may have a width Y2 that is different from the width Y1 of the first mounting structure 4001. The same is true of the second side 2701 and its corresponding second mounting structure 4002.

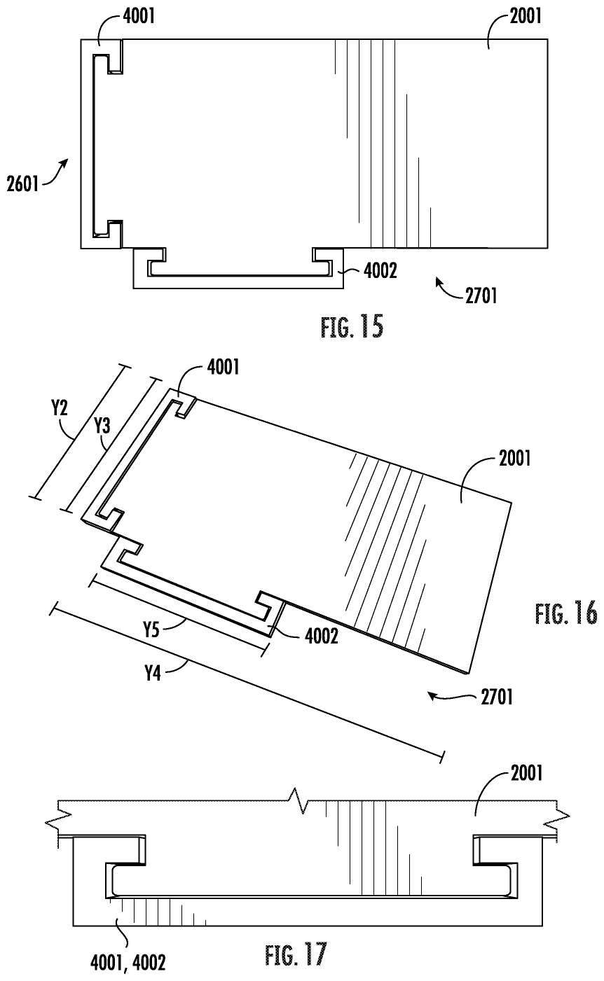

FIGS. 15-17 show an embodiment or implementation which is an alternative to that shown in FIGS. 12-14. FIGS. 15-17 similarly show a first thermal storage cell having a first side 2601 and a second side 2701, each having a male mounting connector (as labeled 3310 in an alternative embodiment discussed herein above). The male mounting connectors 3310 are engaged with a first female mounting structure 4001 and a second female mounting structure 4002. However, in the embodiment of FIGS. 15-17, a width Y2 of the first side 2601 is the same or substantially the same as a width Y3 of the first female mounting structure 4001. Similar to the embodiment of FIGS. 12-14, the embodiment of FIGS. 15-17 illustrate a second side 2701 having a length Y4 which is different from a length Y5 of the second female mounting structure 4002.

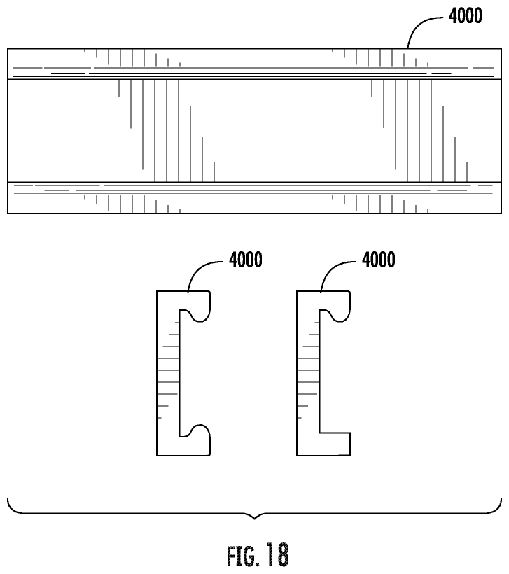

FIG. 18 illustrates a mounting structure 4000 described herein, with two differing shapes of a female mounting connector being shown in the alternative. The embodiments shown are a C-shaped bracket or structure and a similar near-C-shape having a flat bottom connector and a hooked top connector. Such embodiments can be adapted to receive a thermal storage cell (not shown) in a slidable or snap-fit configuration.

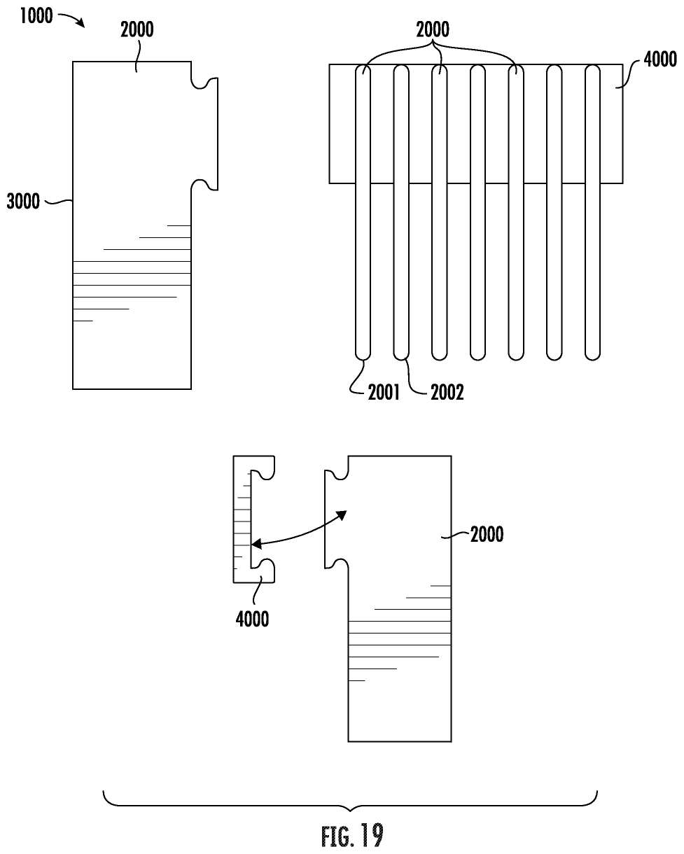

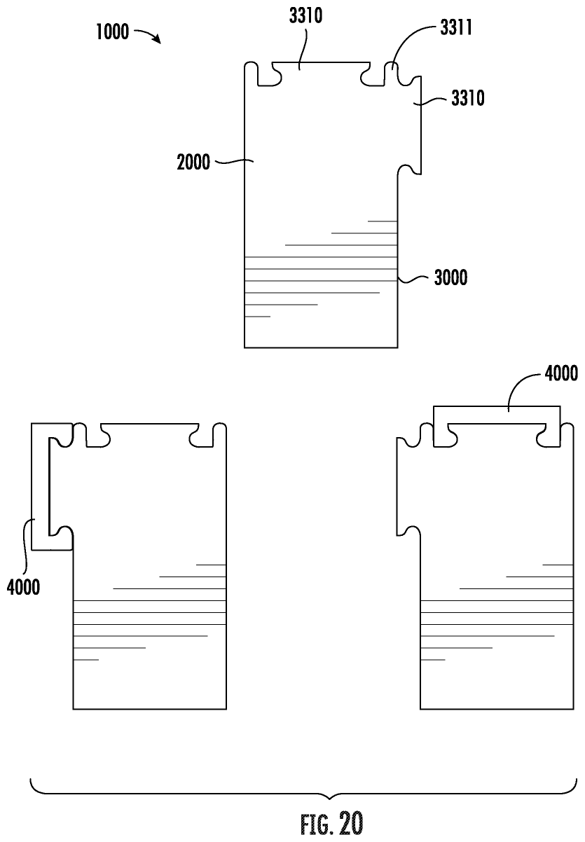

FIG. 19 shows a schematic representation a kit 1000 described herein and how a mounting structure 4000 of such a kit 1000 as seen in FIG. 18 may engage with one or more thermal storage cells 2000, including at least a first thermal storage cell 2001 and a second thermal storage cell 2002. In the embodiment of FIG. 19, the male mounting connector is integral with the container 3000.

FIG. 20 illustrates an implementation of a kit 1000 described herein in which a thermal storage cell 2000 comprises a container 3000 having multiple male mounting connectors 3310 which may engage with a mounting structure 4000 in a variety of orientations. The male mounting connectors 3310 may comprise or include one or more protrusions 3311 configured to engage with the mounting structure 4000. Although the embodiments shown in FIG. 20 illustrate no mounting structure 4000, or only one mounting structure 4000 in each orientation, one having skill in the art would reasonably understand that multiple mounting structures 4000 may be used concurrently as necessary or desired.

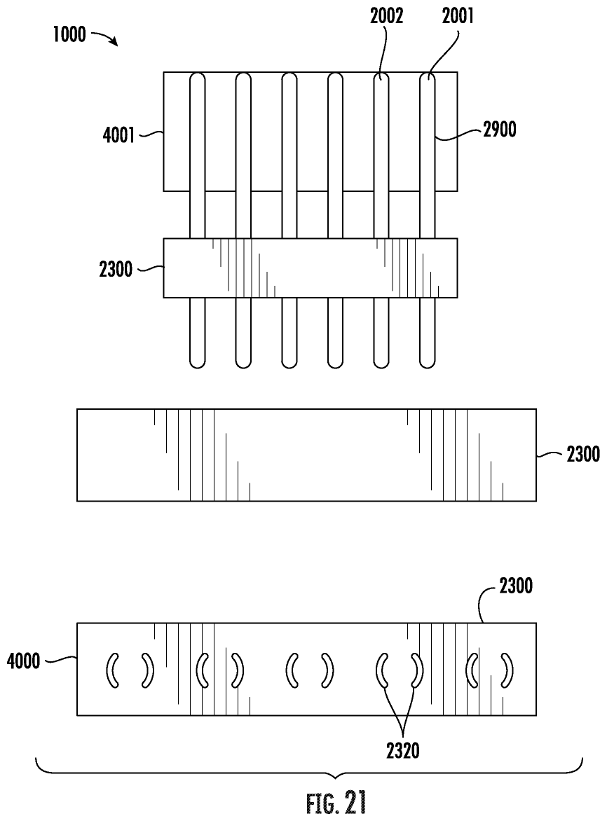

FIG. 21 is a schematic representation of an embodiment of a kit 1000 described herein similar to that shown in FIG. 5. The kit 1000 comprises at least a first thermal storage cell 2001, a second thermal storage cell 2002, and a first mounting structure 4001 associated with both. The kit 1000 further comprises a spacer 2300 which is shown in greater detail. As seen in FIG. 21, the spacer 2300 may contain or comprise integrally formed spacer attachment tabs 2320 which are configured to engage with at least a portion 2900 of a thermal storage cell, such as by snap fit or interference fit.

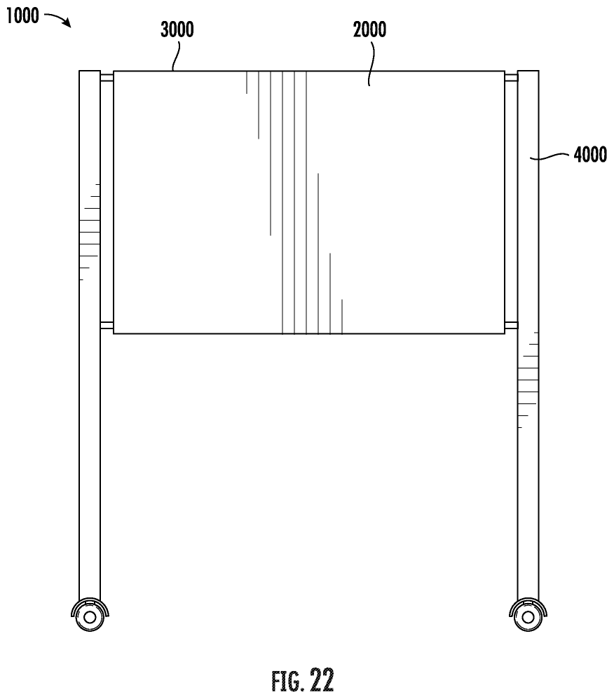

FIG. 22 illustrates a kit 1000 described herein which is portable. The kit 1000 comprises a thermal storage cell 2000 having a container 3000. The kit 1000 further comprises a mounting structure 4000 which has wheels, such as caster wheels, to facilitate movability or portability of the kit.

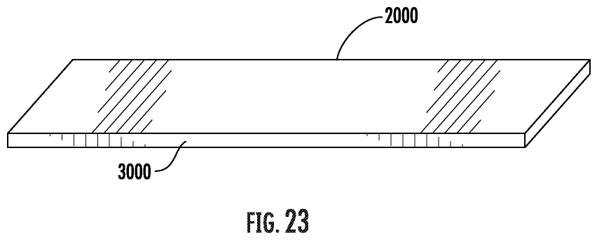

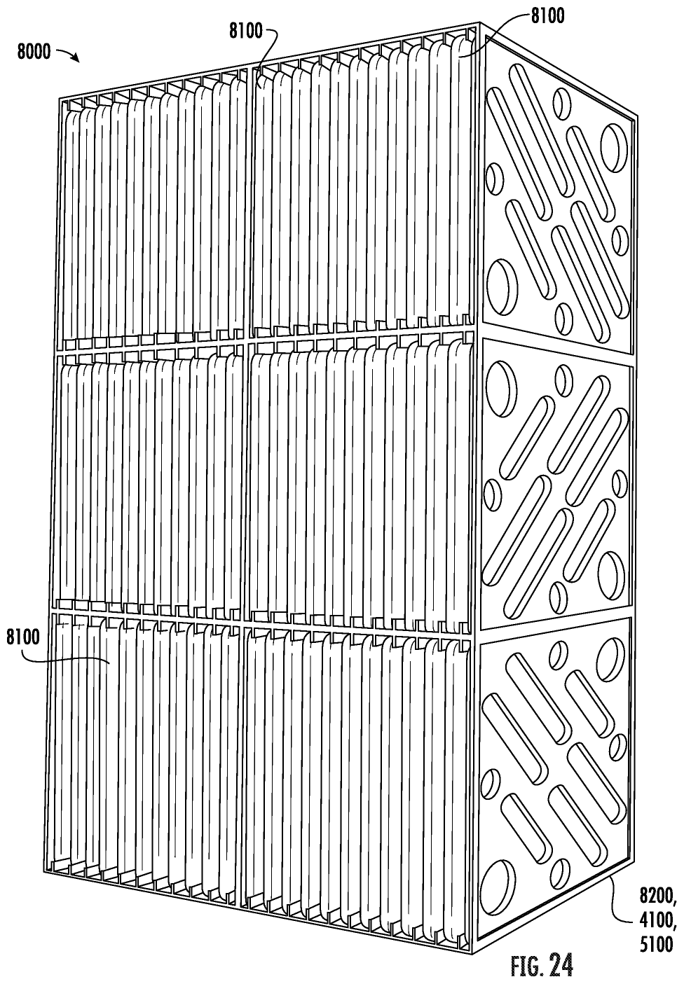

FIG. 23 illustrates a schematic view of a thermal storage cell 2000 comprising a container 3000 in a plate or blade-like configuration.

FIG. 24 illustrates one embodiment of a kit 1000 described herein. The kit 1000 comprises a thermal battery 8000, the thermal battery including a plurality of thermal storage cells 8100. The embodiment of FIG. 24 provides a mounting structure in the form of a frame 4100, and which also constitutes furniture 5100 of the room. In some such embodiments, an open frame 4100 of this type forms an enclosure 8200 which may permit air flow from a first side to a second side. In such an embodiment, the frame 4100 includes or comprises integrally formed protrusions which each form racks or shelves, and the thermal storage cells 8100 may be easily or readily slidably removed or replaced.

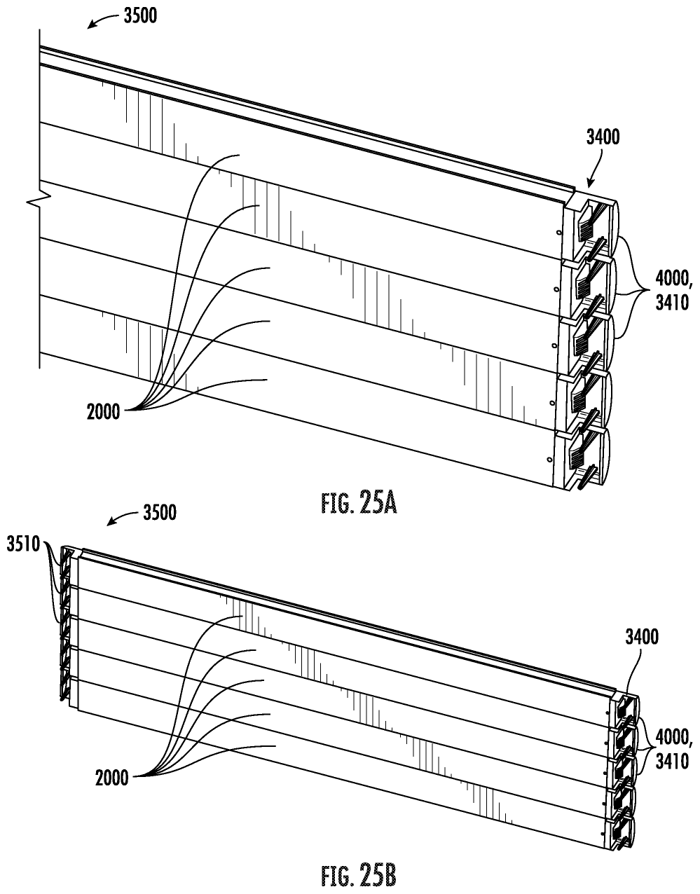

FIGS. 25A-25B illustrate one or more implementations of thermal storage cells 2000 of kits 1000 described herein. The embodiments shown in FIG. 25A are substantially the same as those in FIG. 25B, but with a higher ratio of length to width. In each of these two figures, the containers of the thermal storage cells have a first end 3400 with an associated first end cap 3410. The embodiment of FIG. 25 additionally shows a second end 3500 of the container having a second end cap 3510 associated therewith. In the embodiments shown in FIGS. 25A and 25B, the mounting structure 4000 may be formed in whole or in part by the first and second end caps 3410, 3510.

FIG. 26 illustrates a thermal storage cell 2000 of a kit 1000 described herein. The PCM is not shown for clarity. The container 3000 has a first end 3400, a second end 3500, and an interior volume 3100 which may receive or contain the PCM. The embodiment of FIG. 26 illustrates that a container may have a length X1, a width Y1, and a depth Z1. The length X1 may be substantially longer than a width Y1, to form a length to width ratio of at least 5:1 as described herein above. In the embodiment of FIG. 26, a cross-sectional shape is selected which has one or more (in this case 3) flat or substantially linear sides and at least one rounded side.

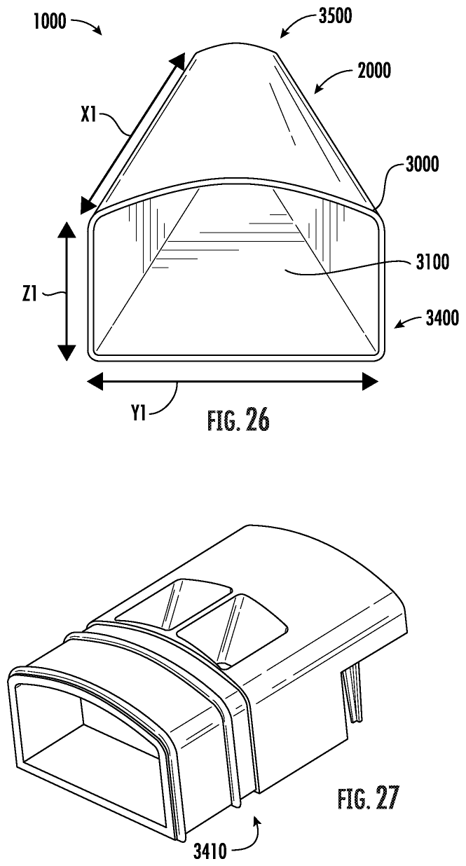

FIG. 27 illustrates a more detailed view of an end cap (such as a first end cap 3410) usable with a container as described herein. The end cap 3410 comprises a number of protrusions and/or recesses which may be used to attach the container to a wall, ceiling, or furniture of a room. Additionally, the end cap 3410 may have ridges adapted to receive one or more sealing members, such as an O-ring.

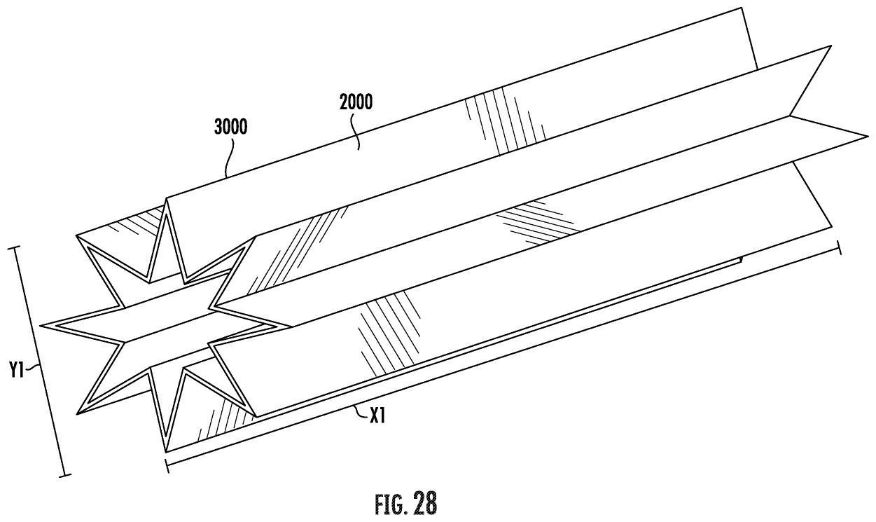

FIG. 28 illustrates one embodiment of a container 3000 of a thermal storage cell 2000 described herein. The container 3000 has a cross-sectional shape which is polygonal and substantially star-shaped, forming a plurality of thermal energy exchange fins along a length X1 thereof.

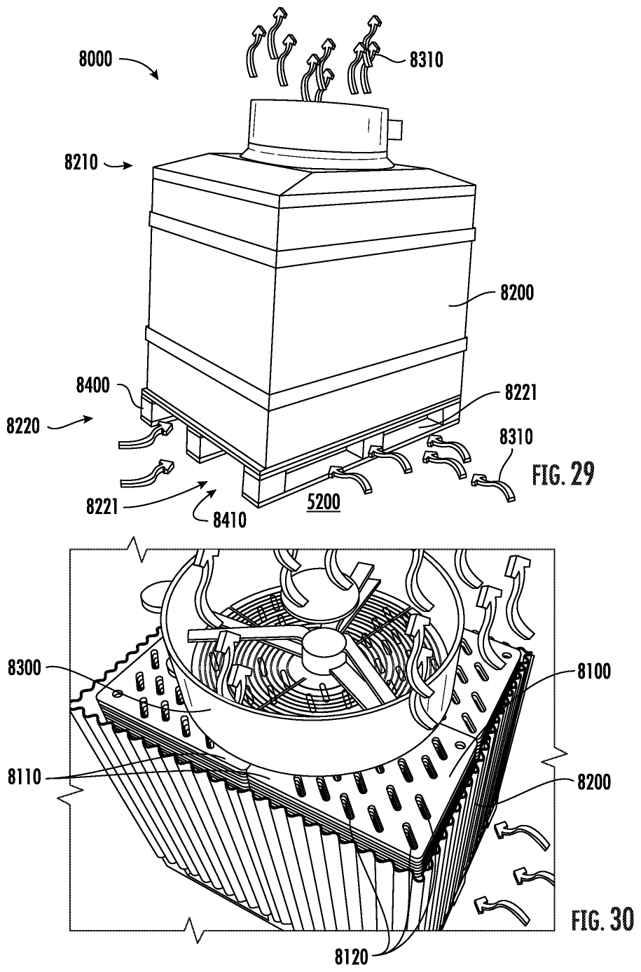

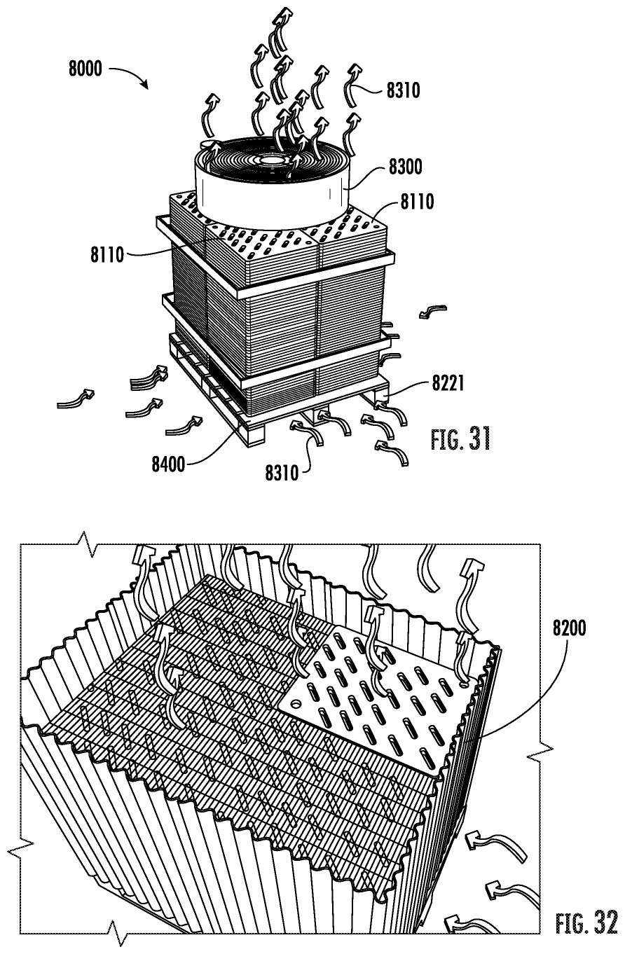

FIGS. 29-32 illustrate one embodiment of a kit described herein. The thermal energy management kit comprises a thermal battery 8000 comprising a plurality of thermal storage cells 8100. The kit further comprises an enclosure 8200, with the plurality of thermal storage cells 8100 being disposed within the enclosure 8200. The kit further comprises a fan 8300 configured to pull air 8310 through the enclosure 8200 across or through the thermal battery 8000 and to exhaust the air 8310 external to the enclosure 8200. The kit shown in FIGS. 29-32 is portable, and includes a spacer 8400 which is, in the depicted embodiments, a pallet as may be used with a forklift. The spacer 8400 forms an air gap beneath a bottom 8220 of the enclosure 8200. The fan 8300 is disposed on a top 8210 of the enclosure 8200. FIG. 29 shows a perspective view of such an assembly. FIG. 30 shows the kit of FIG. 29 with an outer portion or outer layer of the enclosure 8200 removed to more easily see internal components such as the thermal storage cells 8100. The inner layer of the enclosure 8200 in this embodiment comprises or is formed from a corrugated metal. The thermal storage cells 8100 are in a stack 8110. Each of the thermal storage cells 8100 comprise a plurality of air passageways 8120 so that air 8310 may flow freely through the cells 8110. FIG. 31 shows the battery 8000 comprising a stack or stacks 8110 of thermal storage cells without the enclosure. FIG. 32 shows the thermal battery without the fan 8300 to more clearly show the air 8310 and the flow pattern thereof through the stack or stacks 8110 of thermal storage cells.

### IV. EMBODIMENTS

Certain implementations of apparatus and methods consistent with the present disclosure are provided as follows.

Implementation 1. A thermal energy management kit comprising: one or more thermal storage cells, individual thermal storage cells comprising: a container formed from a thermally conductive material and having an interior volume; and a phase change material disposed within the interior volume of the container; and optionally one or more mounting structures, wherein the one or more mounting structures are configured to attach the one or more thermal storage cells to a wall, ceiling, or furniture of a room.

Implementation 2: The kit of implementation 1, wherein the container comprises a mounting connector for coupling or mating to the mounting structures of the kit. Implementation 3: The kit of any of the preceding implementations, wherein: the container comprises a male mounting connector; the one or more mounting structures comprise a female mounting connector; and the male mounting connector of the container mates to the female mounting connector of the mounting structures. Implementation 4: The kit of any of the preceding implementations, wherein the male mounting connector is a protrusion integrally formed with the container. Implementation 5: The kit of implementation 3, wherein the female mounting connector comprises a bracket. Implementation 6: The kit of implementation 5, wherein the bracket is a U-shaped or C-shaped bracket.

Implementation 7: The kit of any of the preceding implementations, wherein the one or more mounting structures comprise a frame. Implementation 8: The kit of implementation 1, wherein: the kit comprises a plurality of thermal storage cells; and the thermal storage cells are configured to attach to the one or more mounting structures in a parallel or substantially parallel configuration. Implementation 9: The kit of implementation 8, wherein the thermal storage cells are separated from one another by an average distance of 0.3 to 3 inches, measured in a direction perpendicular to the parallel or substantially parallel configuration. Implementation 10: The kit of implementation 8 further comprising one or more spacers, wherein: individual thermal storage cells of the plurality of thermal storage cells have a proximal end and a distal end; and the one or more spacers are configured to maintain an average distance between the distal ends of adjacent thermal storage cells attached to or disposed within the one or more mounting structures.

Implementation 11: The kit of any of the preceding implementations, wherein: individual thermal storage cells of the plurality of thermal storage cells have at least one long axis and at least one short axis; and the one or more thermal storage cells are attached to the wall, ceiling, or furniture in a horizontal or substantially horizontal configuration, with the long axis of the individual thermal storage cells being substantially parallel to a floor of the room. Implementation 12: The kit of any of the preceding implementations, wherein, individual thermal storage cells of the plurality of thermal storage cells have at least one long axis and at least one short axis; and the one or more thermal storage cells are attached to the wall, ceiling, or furniture in a vertical or substantially vertical configuration, with the long axis of the individual thermal storage cells being substantially perpendicular to a floor of the room.

Implementation 13: The kit of any of the preceding implementations further comprising at least one fan that directs air flow from a first side of the thermal storage cells to a second side of the thermal storage cells, wherein the first and second sides are in facing opposition to one another. Implementation 14: The kit of implementation 13, wherein the kit comprises a first fan that rotates in a clockwise direction and a second fan that rotates in a counterclockwise direction. Implementation 15: The kit of implementation 13, wherein the kit further comprises a photovoltaic cell or a thermoelectric generator that powers the at least one fan. Implementation 16: The kit of implementation 15, wherein the photovoltaic cell is a thin film photovoltaic cell. Implementation 17: The kit of implementation 16, wherein the photovoltaic cell gathers or harvests energy from ambient light of the room. Implementation 18: The kit of implementation 15, wherein the thermoelectric generator gathers or harvests energy from a temperature gradient within the room.

Implementation 19: The kit of any of the preceding implementations, wherein the kit further comprises a light source. Implementation 20: The kit of implementation 19, wherein the light source is a night light or a safety light.

Implementation 21: The kit of any of the preceding implementations, wherein the phase change material has a phase transition temperature within one of the following ranges:
450-550° C.;
300-550° C.;
70-100° C.;
60-80° C.;
40-50° C.;
16-23° C.;
16-18° C.;
15-20° C.;
6-8° C.; and
−40 to −10° C.

Implementation 22: The kit of any of the preceding implementations, wherein one or more components of the kit is formed from a metal. Implementation 23: The kit of any of the preceding implementations, wherein one or more components of the kit is formed from plastic or a composite material. Implementation 24: The kit of any of the preceding implementations, wherein the furniture comprises a data rack. Implementation 25: The kit of implementation 1, wherein the room is a data room, a data storage center, or an IT closet.

Implementation 26: The kit of implementation 1, wherein: the container has a length, a width, and a depth; and wherein a ratio of the length to the width is at least 5:1. Implementation 27: The kit of implementation 26, wherein the ratio of the length to the width is at least 10:1. Implementation 27: The kit of implementation 26, wherein the container is formed from aluminum or an aluminum alloy. Implementation 28: The kit of implementation 26, wherein: the container has a first end and a second end; and the thermal storage cell further comprises a first end cap disposed at the first end of the container and a second end cap disposed at the second end of the container, the first end cap and the second end cap being configured to seal the first end and the second end to prevent the flow of the phase change material from within the container. Implementation 30: The kit of implementation 29, wherein the thermal storage cell further comprises a plurality of sealing members which, in combination with the container and the first end cap and the second end cap, aids in preventing the flow of the phase change material from within the container. Implementation 31: The kit of implementation 30, wherein the plurality of sealing members are O-rings. Implementation 32: The kit of implementation 30, wherein the plurality of sealing members are formed from an elastomeric material.

Implementation 33: The kit of implementation 30, wherein at least one of the first end cap and the second end cap is configured to be removably attached to the container. Implementation 34: The kit of implementation 33, wherein both of the first end cap and the second end cap are configured to be removably attached to the container. Implementation 35: The kit of implementation 30, wherein at least one of the first end cap and the second cap are configured to be non-removably attached to the container. Implementation 36: The kit of implementation 35, wherein both of the first end cap and the second end cap are configured to be non-removably attached to the container. Implementation 37: The kit of implementation 30, wherein the one or more mounting structures are configured to attach the one or more thermal storage cells to the wall, ceiling, or furniture of the room parallel or substantially parallel to the wall, ceiling, or furniture when attached.

Implementation 38: The kit of implementation 26, wherein: the container has at least one end; and at least one of the one or more mounting structures are configured as an end cap which is adapted to be disposed within or attached to the at least one end while attaching the one or more thermal storage cells to the wall, ceiling, or furniture of the room. Implementation 39: The kit of implementation 38, wherein the end cap is additionally configured to prevent the flow of phase change material from the at least one end.

Implementation 40: The kit of implementation 26, wherein: the container has a first end and a second end opposite the first end; and at least one of the one or more mounting structures are configured as a first end cap which is adapted to be disposed within or attached to the first end while attaching the one or more thermal storage cells to the wall, ceiling, or furniture of the room. Implementation 41: The kit of implementation 40, wherein the first end cap is additionally configured to prevent the flow of phase change material from the first end. Implementation 42: The kit of implementation 41, wherein the one or more mounting structures comprise: the first end cap which is adapted to be disposed within or attached to the first end while attaching the one or more thermal storage cells to the wall, ceiling, or furniture of the room; and a second end cap which is adapted to be disposed within or attached to the second end while attaching the one or more thermal storage cells to the wall, ceiling, or furniture of the room. Implementation 43: The kit of implementation 42, wherein the second end cap is additionally configured to prevent the flow of phase change material from the second end.

Implementation 44: The kit of any of the preceding implementations, wherein the one or more mounting structures are removably attached to the wall, ceiling, or furniture of the room. Implementation 45: The kit of implementation 44, wherein the one or more mounting structures are attached to the wall, ceiling, or furniture of the room with one or more bolts or screws. Implementation 46: The kit of implementation 44, wherein the one or more mounting structures are attached to the wall, ceiling, or furniture of the room with a releasable adhesive.

Implementation 47: The kit of any of the preceding implementations, wherein the one or more mounting structures are non-removably attached to the wall, ceiling, or furniture of the room. Implementation 48: The kit of implementation 47, wherein the one or more mounting structures are bonded or welded to the wall, ceiling, or furniture of the room. Implementation 49: The kit of implementation 48, wherein the one or more mounting structures are welded to the wall, ceiling, or furniture of the room. Implementation 50: The kit of implementation 48, wherein the one or more mounting structures are bonded to the wall, ceiling, or furniture of the room by an adhesive. Implementation 51: The kit of implementation 47, wherein the one or more mounting structures are bonded to the wall, ceiling, or furniture of the room by an epoxy.

Implementation 52: The kit of any of the preceding implementations, wherein: the thermal energy management kit comprises a plurality of the thermal storage cells; and wherein at least one of the one or more mounting structures is configured to attach at least two of the plurality of thermal storage cells to the wall, ceiling, or furniture of the room. Implementation 53: The kit of any of the preceding implementations, wherein the container of the at least one thermal storage cell is configured to slidably engage with at least one of the one or more mounting structures.

Implementation 54: The kit of implementation 53, wherein: the one or more mounting structures individually comprise a first end and a second end; the container of the thermal storage cell comprises a male mounting connector; and the first end of the one or more mounting structures has an opening configured to receive the male mounting connector of the container. Implementation 55: The kit of implementation 54, wherein the second end of the one or more mounting structures has an opening configured to receive the male mounting connector of the container. Implementation 56: The kit of implementation 54, wherein the second end of the one or more mounting structures has an end cap portion integral with or permanently affixed to the one or more mounting structures which is configured to hold a position of the male mounting connector of the container when the male mounting connector is engaged with the one or more mounting structures. Implementation 57: The kit of implementation 54, wherein the one or more mounting structures further comprise at least one removable end cap which is configured to be releasably attached to at least one of the first end and the second end of the one or more mounting structures; and wherein the at least one removable end cap is configured to hold a position of the male mounting connector of the container when the male mounting connector is engaged with the one or more mounting structures.

Implementation 58: The kit of any of the preceding implementations, wherein: the one or more mounting structures are mounted to the wall, ceiling, or furniture of the room; the one or more mounting structures are adapted to receive the one or more thermal storage cells in a first orientation; and while in the first orientation, the one or more thermal storage cells are removable from the one or more mounting structures. Implementation 59: The kit of implementation 58, wherein: the one or more mounting structures are adapted to engage with the one or more thermal storage cells in a second orientation; the second orientation is different from the first orientation; and while in the second orientation, the one or more thermal storage cells are in a locked position which prevents or substantially prevents removal of the one or more thermal storage cells from the one or more mounting structures.

Implementation 60: The kit of any of the preceding implementations, wherein: the one or more mounting structures define a female mounting connector having an opening configured to receive at least a portion of the thermal storage cell. Implementation 61: The kit of implementation 60, wherein: the opening is sized to provide an interference fit when the portion of the thermal storage cell is inserted into the opening. Implementation 62: The kit of implementation 60, wherein: the opening is sized to provide a clearance fit when the portion of the thermal storage cell is inserted into the opening. Implementation 63: The kit of implementation 60, wherein: the opening is sized to provide a transition fit when the portion of the thermal storage cell is inserted into the opening.

Implementation 64: The kit of any of the preceding implementations, wherein the one or more mounting structures comprise at least one hook. Implementation 65: The kit of any of the preceding implementations, wherein the one or more mounting structures snap-fit with the thermal storage cell. Implementation 66: The kit of any of the preceding implementations, wherein the one or more mounting structures are configured to engage directly with the container of the one or more thermal storage cells. Implementation 67: The kit of any of the preceding implementations, wherein the one or more mounting structures are configured to engage with an intermediary connector, and the intermediary connector is configured to engage with the container of the one or more thermal storage cells.

Implementation 68: The kit of any of the preceding implementations, wherein: the one or more thermal storage cells comprises a first thermal storage cell; the one or more mounting structures comprises a first mounting structure associated with the first thermal storage cell and a second mounting structure associated with the first thermal storage cell. Implementation 69: The kit of implementation 68, wherein the first mounting structure is associated with a first side of the first thermal storage cell and the second mounting structure is associated with a second side of the first thermal storage cell. Implementation 70: The kit of implementation 69, wherein: the first side of the first thermal storage cell defines a width; the first mounting structure defines a width; and the width of the first side of the first thermal storage cell is the same as the width of the first mounting structure. Implementation 71: The kit of implementation 69, wherein: the first side of the first thermal storage cell defines a width; the first mounting structure defines a width; and the width of the first side of the first thermal storage cell is the same as the width of the first mounting structure. Implementation 72: The kit of implementation 69, wherein: the second side of the first thermal storage cell defines a width; the second mounting structure defines a width; and the width of the second side of the first thermal storage cell Implementation 70: The kit of implementation 69, wherein: the first side of the first thermal storage cell defines a width; the first mounting structure defines a width; and the width of the first side of the first thermal storage cell is the same as the width of the first mounting structure. Implementation 71: The kit of implementation 69, wherein: the first side of the first thermal storage cell defines a width; the first mounting structure defines a width; and the width of the first side of the first thermal storage cell is different from the width of the first mounting structure. Implementation 72: The kit of implementation 69, wherein: the second side of the first thermal storage cell defines a width; the second mounting structure defines a width; and the width of the second side of the first thermal storage cell is different from the width of the second mounting structure. Implementation 73: The kit of implementation 68, wherein the first mounting structure and the second mounting structure are both associated with a first side of the thermal storage cell.

Implementation 74: A thermal energy management kit comprising: a thermal battery comprising a plurality of thermal storage cells; an enclosure, the plurality of thermal storage cells being disposed within the enclosure; and at least one fan configured to pull air through the enclosure across or through the thermal battery and to exhaust the air external to the enclosure, wherein the thermal energy management kit is portable. Implementation 75: The kit of implementation 74, wherein the thermal storage cells are arranged in one or more stacks. Implementation 76: The kit of implementation 74, wherein individual thermal storage cells of the plurality of thermal storage cells comprise an air passageway. Implementation 77: The kit of implementation 74, wherein: the enclosure has a top and a bottom; the fan is disposed on the top of the enclosure; and the bottom of the enclosure has at least one air inlet opening. Implementation 78: The kit of implementation 77 further comprising a spacer to provide an air gap between the bottom of the enclosure and a floor of an environment. Implementation 79: The kit of implementation 78, wherein the spacer is integral with the enclosure. Implementation 80: The kit of claim 78, wherein the spacer is separate from the enclosure and adapted for the enclosure to be seated on the spacer. Implementation 81: The kit of implementation 78, wherein the spacer is a pallet.

Implementation 82: A method of managing the temperature of a room, the method comprising: disposing one or more kits of any of the preceding implementations in the room. Implementation 83: The method of implementation 82, wherein the room is a data center, a data storage room, or an IT closet. Implementation 84: The method of implementation 82, wherein the room has a desired average temperature between 15° C. and 30° C. Implementation 85: The method of implementation 82, wherein the room has a desired average temperature between 15° C. and 40° C. Implementation 86: The method of implementation 82, wherein the room is a refrigerated room or a freezer. Implementation 87: The method of implementation 85, wherein the room has a desired average temperature between −10° C. and 10° C. Implementation 88: The method of implementation 82 further comprising: changing the phase of the phase change material from a first phase to a second phase by exposing the phase change material to an ambient temperature in the room below a phase change temperature of the phase change material; and reverting the phase change material to the first phase by heating the room with an HVAC system of the room. Implementation 89: The method of implementation 88, wherein the HVAC system is activated or deactivated by a thermostat disposed within the interior of the room. Implementation 90: The method of implementation 89 further comprising: changing the phase of the phase change material from a first phase to a second phase by exposing the phase change material to an ambient temperature of the room above a phase change temperature of the phase change material; and reverting the phase change material to the first change by cooling the room with an HVAC system of the room. Implementation 91: The method of implementation 90, wherein the HVAC system is activated or deactivated by a thermostat disposed within the interior of the room.

Various implementations of devices and methods have been described in fulfillment of various objectives of the present disclosure. It should be recognized that these implementations are merely illustrative of the principles of the present disclosure. Numerous modifications and adaptations thereof will be readily apparent to those skilled in the art without departing from the spirit and scope of the present disclosure. For example, individual steps of methods described herein can be carried out in any manner not inconsistent with the objectives of the present disclosure, and various configurations or adaptations of devices described herein may be used.

1. A thermal energy management kit comprising:
one or more thermal storage cells, individual thermal storage cells comprising:
a container formed from a thermally conductive material and having an interior volume; and
a phase change material disposed within the interior volume of the container; and one or more mounting structures,
wherein the one or more mounting structures are configured to attach the one or more thermal storage cells to a wall, ceiling, or furniture of a room.

2. The kit of claim 1, wherein the container comprises a mounting connector for coupling or mating to the mounting structures of the kit.

3. The kit of claim 2, wherein:
the container comprises a male mounting connector;
the one or more mounting structures comprise a female mounting connector; and
the male mounting connector of the container mates to the female mounting connector of the mounting structures.

4. The kit of claim 3, wherein the male mounting connector is a protrusion integrally formed with the container.

5. The kit of claim 3, wherein the female mounting connector comprises a bracket.

6. The kit of claim 5, wherein the bracket is a U-shaped or C-shaped bracket.

7. The kit of claim 1, wherein the one or more mounting structures comprise a frame.

8. The kit of claim 1, wherein:
the kit comprises a plurality of thermal storage cells; and
the thermal storage cells are configured to attach to the one or more mounting structures in a parallel or substantially parallel configuration.

9. The kit of claim 8, wherein the thermal storage cells are separated from one another by an average distance of 0.3 to 3 inches, measured in a direction perpendicular to the parallel or substantially parallel configuration.

10. The kit of claim 8 further comprising one or more spacers, wherein:
individual thermal storage cells of the plurality of thermal storage cells have a proximal end and a distal end; and
the one or more spacers are configured to maintain an average distance between the distal ends of adjacent thermal storage cells attached to or disposed within the one or more mounting structures.

11. The kit of claim 1, wherein:
individual thermal storage cells of the plurality of thermal storage cells have at least one long axis and at least one short axis; and
the one or more thermal storage cells are attached to the wall, ceiling, or furniture in a horizontal or substantially horizontal configuration, with the long axis of the individual thermal storage cells being substantially parallel to a floor of the room.

12. The kit of claim 1, wherein,
individual thermal storage cells of the plurality of thermal storage cells have at least one long axis and at least one short axis; and
the one or more thermal storage cells are attached to the wall, ceiling, or furniture in a vertical or substantially vertical configuration, with the long axis of the individual thermal storage cells being substantially perpendicular to a floor of the room.

13. The kit of claim 1 further comprising at least one fan that directs air flow from a first side of the thermal storage cells to a second side of the thermal storage cells, wherein the first and second sides are in facing opposition to one another.

14. The kit of claim 13, wherein the kit comprises a first fan that rotates in a clockwise direction and a second fan that rotates in a counterclockwise direction.

15. The kit of claim 13, wherein the kit further comprises a photovoltaic cell or a thermoelectric generator that powers the at least one fan.

16. The kit of claim 15, wherein the photovoltaic cell is a thin film photovoltaic cell.

17. The kit of claim 16, wherein the photovoltaic cell gathers or harvests energy from ambient light of the room.

18. The kit of claim 15, wherein the thermoelectric generator gathers or harvests energy from a temperature gradient within the room.

19. The kit of claim 1, wherein the kit further comprises a light source.

20. The kit of claim 19, wherein the light source is a night light or a safety light.

21. The kit of claim 1, wherein the phase change material has a phase transition temperature within one of the following ranges:
450-550° C.;
300-550° C.;
70-100° C.;
60-80° C.;
40-50° C.;
16-23° C.;
16-18° C.;
15-20° C.;
6-8° C.; and
−40 to −10° C.

22. The kit of claim 1, wherein one or more components of the kit is formed from a metal.

23. The kit of claim 1, wherein one or more components of the kit is formed from plastic or a composite material.

24. The kit of claim 1, wherein the furniture comprises a data rack.

25. The kit of claim 1, wherein the room is a data room, a data storage center, or an IT closet.

26. The kit of claim 1, wherein:
the container has a length, a width, and a depth; and
wherein a ratio of the length to the width is at least 5:1.

27. The kit of claim 26, wherein the ratio of the length to the width is at least 10:1.

28. The kit of claim 26, wherein the container is formed from aluminum or an aluminum alloy.

29. The kit of claim 26, wherein:
the container has a first end and a second end; and
the thermal storage cell further comprises a first end cap disposed at the first end of the container and a second end cap disposed at the second end of the container, the first end cap and the second end cap being configured to seal the first end and the second end to prevent the flow of the phase change material from within the container.

30. The kit of claim 29, wherein the thermal storage cell further comprises a plurality of sealing members which, in combination with the container and the first end cap and the second end cap, aids in preventing the flow of the phase change material from within the container.

31. The kit of claim 30, wherein the plurality of sealing members are O-rings.

32. The kit of claim 30, wherein the plurality of sealing members are formed from an elastomeric material.

33. The kit of claim 30, wherein at least one of the first end cap and the second end cap is configured to be removably attached to the container.

34. The kit of claim 33, wherein both of the first end cap and the second end cap are configured to be removably attached to the container.

35. The kit of claim 30, wherein at least one of the first end cap and the second cap are configured to be non-removably attached to the container.

36. The kit of claim 35, wherein both of the first end cap and the second end cap are configured to be non-removably attached to the container.

37. The kit of claim 30, wherein the one or more mounting structures are configured to attach the one or more thermal storage cells to the wall, ceiling, or furniture of the room parallel or substantially parallel to the wall, ceiling, or furniture when attached.

38. The kit of claim 26, wherein:
the container has at least one end; and
at least one of the one or more mounting structures are configured as an end cap which is adapted to be disposed within or attached to the at least one end while attaching the one or more thermal storage cells to the wall, ceiling, or furniture of the room.

39. The kit of claim 38, wherein the end cap is additionally configured to prevent the flow of phase change material from the at least one end.

40. The kit of claim 26, wherein:
the container has a first end and a second end opposite the first end; and
at least one of the one or more mounting structures are configured as a first end cap which is adapted to be disposed within or attached to the first end while attaching the one or more thermal storage cells to the wall, ceiling, or furniture of the room.

41. The kit of claim 40, wherein the first end cap is additionally configured to prevent the flow of phase change material from the first end.

42. The kit of claim 41, wherein the one or more mounting structures comprise:
the first end cap which is adapted to be disposed within or attached to the first end while attaching the one or more thermal storage cells to the wall, ceiling, or furniture of the room; and
a second end cap which is adapted to be disposed within or attached to the second end while attaching the one or more thermal storage cells to the wall, ceiling, or furniture of the room.

43. The kit of claim 42, wherein the second end cap is additionally configured to prevent the flow of phase change material from the second end.

44. The kit of claim 1, wherein the one or more mounting structures are removably attached to the wall, ceiling, or furniture of the room.

45. The kit of claim 44, wherein the one or more mounting structures are attached to the wall, ceiling, or furniture of the room with one or more bolts or screws.

46. The kit of claim 44, wherein the one or more mounting structures are attached to the wall, ceiling, or furniture of the room with a releasable adhesive.

47. The kit of claim 1, wherein the one or more mounting structures are non-removably attached to the wall, ceiling, or furniture of the room.

48. The kit of claim 47, wherein the one or more mounting structures are bonded or welded to the wall, ceiling, or furniture of the room.

49. The kit of claim 48, wherein the one or more mounting structures are welded to the wall, ceiling, or furniture of the room.

50. The kit of claim 48, wherein the one or more mounting structures are bonded to the wall, ceiling, or furniture of the room by an adhesive.

51. The kit of claim 47, wherein the one or more mounting structures are bonded to the wall, ceiling, or furniture of the room by an epoxy.

52. The kit of claim 1, wherein:
the thermal energy management kit comprises a plurality of the thermal storage cells; and
wherein at least one of the one or more mounting structures is configured to attach at least two of the plurality of thermal storage cells to the wall, ceiling, or furniture of the room.

53. The kit of claim 1, wherein the container of the at least one thermal storage cell is configured to slidably engage with at least one of the one or more mounting structures.

54. The kit of claim 53, wherein:
the one or more mounting structures individually comprise a first end and a second end;
the container of the thermal storage cell comprises a male mounting connector; and
the first end of the one or more mounting structures has an opening configured to receive the male mounting connector of the container.

55. The kit of claim 54, wherein the second end of the one or more mounting structures has an opening configured to receive the male mounting connector of the container.

56. The kit of claim 54, wherein the second end of the one or more mounting structures has an end cap portion integral with or permanently affixed to the one or more mounting structures which is configured to hold a position of the male mounting connector of the container when the male mounting connector is engaged with the one or more mounting structures.

57. The kit of claim 54, wherein the one or more mounting structures further comprise at least one removable end cap which is configured to be releasably attached to at least one of the first end and the second end of the one or more mounting structures; and
wherein the at least one removable end cap is configured to hold a position of the male mounting connector of the container when the male mounting connector is engaged with the one or more mounting structures.

58. The kit of claim 1, wherein:
the one or more mounting structures are mounted to the wall, ceiling, or furniture of the room;
the one or more mounting structures are adapted to receive the one or more thermal storage cells in a first orientation; and
while in the first orientation, the one or more thermal storage cells are removable from the one or more mounting structures.

59. The kit of claim 58, wherein:
the one or more mounting structures are adapted to engage with the one or more thermal storage cells in a second orientation;
the second orientation is different from the first orientation; and
while in the second orientation, the one or more thermal storage cells are in a locked position which prevents or substantially prevents removal of the one or more thermal storage cells from the one or more mounting structures.

60. The kit of claim 1, wherein:
the one or more mounting structures define a female mounting connector having an opening configured to receive at least a portion of the thermal storage cell.

61. The kit of claim 60, wherein:
the opening is sized to provide an interference fit when the portion of the thermal storage cell is inserted into the opening.

62. The kit of claim 60, wherein:
the opening is sized to provide a clearance fit when the portion of the thermal storage cell is inserted into the opening.

63. The kit of claim 60, wherein:
the opening is sized to provide a transition fit when the portion of the thermal storage cell is inserted into the opening.

64. The kit of claim 1, wherein the one or more mounting structures comprise at least one hook.

65. The kit of claim 1, wherein the one or more mounting structures snap-fit with the thermal storage cell.

66. The kit of claim 1, wherein the one or more mounting structures are configured to engage directly with the container of the one or more thermal storage cells.

67. The kit of claim 1, wherein the one or more mounting structures are configured to engage with an intermediary connector, and the intermediary connector is configured to engage with the container of the one or more thermal storage cells.

68. The kit of claim 1, wherein:
the one or more thermal storage cells comprises a first thermal storage cell;
the one or more mounting structures comprises a first mounting structure associated with the first thermal storage cell and a second mounting structure associated with the first thermal storage cell.

69. The kit of claim 68, wherein the first mounting structure is associated with a first side of the first thermal storage cell and the second mounting structure is associated with a second side of the first thermal storage cell.

70. The kit of claim 69, wherein:
the first side of the first thermal storage cell defines a width;
the first mounting structure defines a width; and
the width of the first side of the first thermal storage cell is the same as the width of the first mounting structure.

71. The kit of claim 69, wherein:
the first side of the first thermal storage cell defines a width;
the first mounting structure defines a width; and
the width of the first side of the first thermal storage cell is different from the width of the first mounting structure.

72. The kit of claim 69, wherein:
the second side of the first thermal storage cell defines a width;
the second mounting structure defines a width; and
the width of the second side of the first thermal storage cell is different from the width of the second mounting structure.

73. The kit of claim 68, wherein the first mounting structure and the second mounting structure are both associated with a first side of the thermal storage cell.

74. A thermal energy management kit comprising:
a thermal battery comprising a plurality of thermal storage cells;
an enclosure, the plurality of thermal storage cells being disposed within the enclosure; and
at least one fan configured to pull air through the enclosure across or through the thermal battery and to exhaust the air external to the enclosure,
wherein the thermal energy management kit is portable.

75. The kit of claim 74, wherein the thermal storage cells are arranged in one or more stacks.

76. The kit of claim 74, wherein individual thermal storage cells of the plurality of thermal storage cells comprise an air passageway.

77. The kit of claim 74, wherein:
the enclosure has a top and a bottom;
the fan is disposed on the top of the enclosure; and
the bottom of the enclosure has at least one air inlet opening.

78. The kit of claim 77 further comprising a spacer to provide an air gap between the bottom of the enclosure and a floor of an environment.

79. The kit of claim 78, wherein the spacer is integral with the enclosure.

80. The kit of claim 78, wherein the spacer is separate from the enclosure and adapted for the enclosure to be seated on the spacer.

81. The kit of claim 78, wherein the spacer is a pallet.

82. A method of managing the temperature of a room, the method comprising:
disposing one or more kits of claim 1 in the room.

83. The method of claim 82, wherein the room is a data center, a data storage room, or an IT closet.

84. The method of claim 82, wherein the room has a desired average temperature between 15° C. and 30° C.

85. The method of claim 82, wherein the room has a desired average temperature between 15° C. and 40° C.

86. The method of claim 82, wherein the room is a refrigerated room or a freezer.

87. The method of claim 85, wherein the room has a desired average temperature between −10° C. and 10° C.

88. The method of claim 82 further comprising:
changing the phase of the phase change material from a first phase to a second phase by exposing the phase change material to an ambient temperature in the room below a phase change temperature of the phase change material; and
reverting the phase change material to the first phase by heating the room with an HVAC system of the room.

89. The method of claim 88, wherein the HVAC system is activated or deactivated by a thermostat disposed within the interior of the room.

90. The method of claim 89 further comprising:
changing the phase of the phase change material from a first phase to a second phase by exposing the phase change material to an ambient temperature of the room above a phase change temperature of the phase change material; and
reverting the phase change material to the first change by cooling the room with an HVAC system of the room.

91. The method of claim 90, wherein the HVAC system is activated or deactivated by a thermostat disposed within the interior of the room.
